(19) United States
(12) Patent Application Publication
(10) Pub. No.: US 2026/0059882 A1
(43) Pub. Date: Feb. 26, 2026

(54) IMAGE SENSOR

(71) Applicant: Samsung Electronics Co., Ltd., Suwon-si (KR)

(72) Inventors: Kook Tae Kim, Suwon-si (KR); Jaeuk Shin, Suwon-si (KR); Jongmin Jeon, Suwon-si (KR); Taeksoo Jeon, Suwon-si (KR)

(21) Appl. No.: 19/215,796

(22) Filed: May 22, 2025

(30) Foreign Application Priority Data
Aug. 20, 2024 (KR) 10-2024-0111503

(51) Int. Cl. H10F 39/00

(52) U.S. Cl. CPC H10F 39/807; H10F 39/8053; H10F 39/8063; H10F 39/811

(57) ABSTRACT

An image sensor may include a semiconductor substrate having first and second surfaces, and a pixel isolation structure vertically extending into the semiconductor substrate and defining pixel regions. The pixel isolation structure may include a sidewall insulating pattern in contact with the semiconductor substrate, a first buried pattern on the sidewall insulating pattern, and a second buried pattern on the first buried pattern. A first isolation portion of the pixel isolation structure may extend in a first direction, a second isolation portion of the pixel isolation structure may extend in a second direction, and a third isolation portion of the pixel isolation structure may be at an intersection of the first and the second isolation portions. The first buried pattern may include sidewall portions on the sidewall insulating pattern and a connection portion extending between the sidewall portions, in each of the first to third isolation portions.

### CROSS-REFERENCE TO RELATED APPLICATIONS

This U.S. non-provisional patent application claims priority under 35 U.S.C. § 119 to Korean Patent Application No. 10-2024-0111503, filed on Aug. 20, 2024, in the Korean Intellectual Property Office, the entire contents of which are hereby incorporated by reference.

### TECHNICAL FIELD

The present disclosure herein relates to an image sensor, and more particularly, to an image sensor having improved electrical and optical characteristics.

### BACKGROUND OF THE INVENTION

Image sensors may convert an optical image into an electric signal. With recent developments in the computer and communications industry, demands for image sensors having improved performance are increasing for digital cameras, camcorders, personal communication systems (PCSs), game devices, security cameras, medical micro cameras, and the like.

Image sensors may include a charge coupled device (CCD) and a CMOS image sensor. Since CMOS image sensors enable integration of a signal processing chip into a single chip, products of CMOS image sensors may be reduced in size. CMOS image sensors have very low power consumption and thus may be applicable to products with a limited battery capacity. Furthermore, since CMOS image sensors are compatible with CMOS process technology, the manufacturing cost of CMOS image sensors may be reduced. Therefore, the use of CMOS image sensors is rapidly increasing since high-resolution CMOS image sensors can be achieved with the development of technology.

### SUMMARY OF THE INVENTION

Aspects of the present disclosure provide an image sensor having improved electrical and optical characteristics.

However, aspects of the present disclosure are not limited to the above, and other aspects not mentioned will be clearly understood by those skilled in the art by referencing the present disclosure given below.

Some embodiments of the inventive concept provide an image sensor including: a semiconductor substrate having a first surface and a second surface opposite to the first surface; and a pixel isolation structure vertically extending into the semiconductor substrate and defining a plurality of pixel regions, wherein the pixel isolation structure includes: a sidewall insulating pattern in contact with the semiconductor substrate; a first buried pattern on the sidewall insulating pattern; and a second buried pattern on the first buried pattern, wherein a first isolation portion of the pixel isolation structure extends in a first direction, a second isolation portion of the pixel isolation structure extends in a second direction intersecting the first direction, and a third isolation portion of the pixel isolation structure is at an intersection of the first isolation portion and the second isolation portion, and wherein the first buried pattern includes sidewall portions on the sidewall insulating pattern and a connection portion extending between the sidewall portions, in each of the first, second, and third isolation portions.

In some embodiments of the inventive concept, an image sensor includes: a semiconductor substrate having a first surface and a second surface opposite to the first surface; and a pixel isolation structure vertically extending into the semiconductor substrate and defining a plurality of pixel regions, wherein the pixel isolation structure includes: a sidewall insulating pattern in contact with the semiconductor substrate; a conductive pattern on the sidewall insulating pattern; and a buried pattern on the conductive pattern, wherein a first isolation portion of the pixel isolation structure extends in a first direction, a second isolation portion of the pixel isolation structure extends in a second direction intersecting the first direction, and a third isolation portion of the pixel isolation structure is at an intersection of the first isolation portion and the second isolation portion, and wherein the conductive pattern includes sidewall portions on the sidewall insulating pattern and a connection portion extending between the sidewall portions, in each of the first, second, and third isolation portions.

In some embodiments of the inventive concept, an image sensor includes: a semiconductor substrate of a first conductivity type and having a first surface and a second surface opposite to each other; a pixel isolation structure vertically extending into the semiconductor substrate and defining pixel regions; a photoelectric conversion region in the semiconductor substrate in a respective one of the pixel regions and including second conductivity type impurities; a device isolation film adjacent to the first surface of the semiconductor substrate and defining an active portion in the semiconductor substrate in the respective one of the pixel regions; a transfer gate electrode on the active portion of the respective one of the pixel regions; a contact plug extending into a portion of the pixel isolation structure and electrically connected to a first buried pattern of the pixel isolation structure; color filters on the second surface of the semiconductor substrate and corresponding to respective ones of the pixel regions; a lattice structure between adjacent ones of the color filters; and micro lenses on respective ones of the color filters, wherein the pixel isolation structure includes: a sidewall insulating pattern in contact with the semiconductor substrate; the first buried pattern on the sidewall insulating pattern; and a second buried pattern on the first buried pattern, wherein a first isolation portion of the pixel isolation structure extends in a first direction, a second isolation portion of the pixel isolation structure extends in a second direction intersecting the first direction, and a third isolation portion of the pixel isolation structure is at an intersection of the first isolation portion and the second isolation portion, and wherein the first buried pattern includes sidewall portions on the sidewall insulating pattern and a connection portion extending between the sidewall portions in each of the first, second, and third isolation portions.

Details about example embodiments are included in the detailed description and the drawings.

### BRIEF DESCRIPTION OF THE FIGURES

The accompanying drawings are included to provide a further understanding of the inventive concept, and are incorporated in and constitute a part of this specification. The drawings illustrate example embodiments of the inventive concept and, together with the description, serve to explain aspects of the inventive concept. In the drawings:

FIG. 1 is a block diagram illustrating an image sensor according to embodiments of the inventive concept;

FIGS. 2A and 2B are circuit diagrams illustrating a unit pixel of an image sensor according to embodiments of the inventive concept;

FIG. 3 is a plan view of a portion of an image sensor according to embodiments of the inventive concept;

FIGS. 4A, 4B, and 4C are cross-sectional views of an image sensor, taken along line A-A′, line B-B′, and line C-C′ of FIG. 3, respectively, according to embodiments of the inventive concept;

FIGS. 5A and 6A are enlarged views of portion P1 of FIG. 4A;

FIGS. 5B, 5C, and 6B are enlarged views of portion P2 of FIG. 4B;

FIG. 7A is a cross-sectional view of an image sensor, taken along line A-A′ of FIG. 3, according to embodiments of the inventive concept;

FIGS. 7B and 7C are cross-sectional views of an image sensor, taken along line B-B′ of FIG. 3, according to embodiments of the inventive concept;

FIGS. 8A and 9A are enlarged views of portion P1 of FIG. 7A illustrating an image sensor according to embodiments of the inventive concept;

FIGS. 8B and 9B are enlarged views of portion P2 of FIG. 7B illustrating an image sensor according to embodiments of the inventive concept;

FIG. 8C is an enlarged view of portion P2 of FIG. 7C illustrating an image sensor according to embodiments of the inventive concept;

FIGS. 10A, 10B, 11A, 11B, 12A, 12B, 13A, 13B, 14A, 14B, 15A, 15B, 16A, 16B, 17A, 17B, 18A, 18B, 19A, 19B, 20A, and 20B are cross-sectional views taken along line A-A′ and line B-B′ of FIG. 3 illustrating a method for manufacturing an image sensor according to embodiments of the inventive concept;

FIGS. 21A, 21B, 22A, 22B, 23A, and 23B are cross-sectional views taken along line A-A′ and line B-B′ of FIG. 3 illustrating a method for manufacturing an image sensor according to embodiments of the inventive concept;

FIGS. 24A, 24B, 25A, 25B, 26A, and 26B are cross-sectional views taken along line A-A′ and line B-B′ of FIG. 3 illustrating a method for manufacturing an image sensor according to embodiments of the inventive concept;

FIG. 27 is a schematic plan view of an image sensor including a semiconductor device according to embodiments of the inventive concept; and

FIGS. 28 and 29 are cross-sectional views of an image sensor, taken along line I-I′ of FIG. 27, according to embodiments of the inventive concept.

### DETAILED DESCRIPTION

Hereinafter, an image sensor according to example embodiments of the inventive concept will be described in detail with reference to the drawings.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure. Further, as used herein, the term “and/or”includes any and all combinations of one or more of the associated listed items.

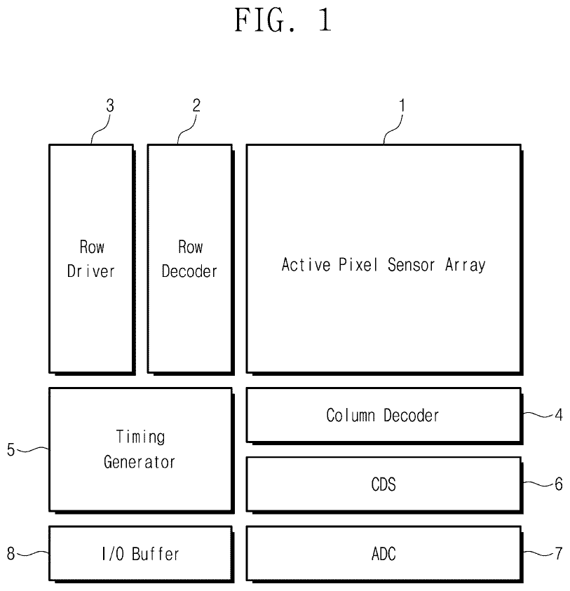

FIG. 1 is a block diagram illustrating an image sensor according to embodiments of the inventive concept.

Referring to FIG. 1, the image sensor includes an active pixel sensor array 1, a row decoder 2, a row driver 3, a column decoder 4, a timing generator 5, a correlated double sampler (CDS) 6, an analog-to-digital converter (ADC) 7, and an input/output (I/O) buffer 8.

The active pixel sensor array 1 includes a plurality of unit pixels arranged two-dimensionally and converts an optical signal into an electric signal. The active pixel sensor array 1 may be driven by a plurality of driving signals such as a pixel selection signal, a reset signal, and a charge transfer signal from the row driver 3. Furthermore, the converted electric signal is provided to the CDS 6.

The row driver 3 provides the active pixel sensor array 1 with a plurality of driving signals for driving a plurality of unit pixels according to a result of decoding by the row decoder 2. When the unit pixels are arranged in a matrix form, the driving signals may be provided for each row.

The timing generator 5 provides a timing signal and a control signal to the row decoder 2 and the column decoder 4.

The CDS 6 receives, holds, and samples the electric signal generated by the active pixel sensor array 1. The CDS 6 double samples a particular noise level and a signal level due to the electric signal, and outputs a difference level corresponding to a difference between the noise level and the signal level.

The ADC 7 converts an analog signal corresponding to the difference level output from the CDS 6 into a digital signal, and outputs the digital signal.

The input/output buffer 8 latches digital signals, and the latched digital signals are sequentially output to an image signal processing unit (not shown) according to a result of decoding by the column decoder 4.

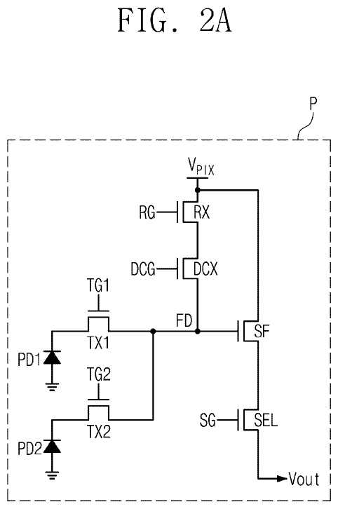

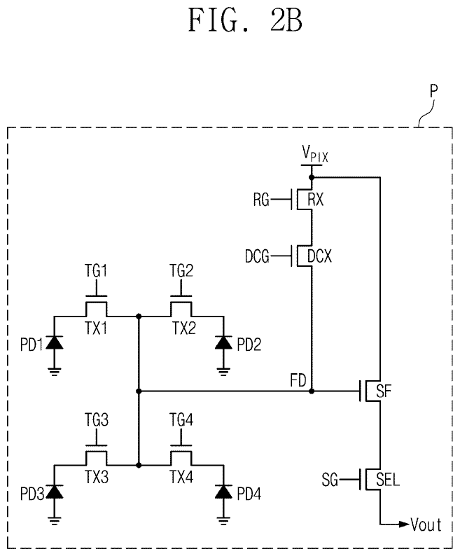

FIGS. 2A and 2B are circuit diagrams illustrating a unit pixel of an image sensor according to embodiments of the inventive concept.

Referring to FIG. 2A, a unit pixel P may include first and second photoelectric conversion elements PD1 and PD2, first and second transfer transistors TX1 and TX2, a floating diffusion region FD (or charge detection node) connected in common to the first and second transfer transistors TX1 and TX2, and a plurality of pixel transistors. In other words, the floating diffusion region FD may be electrically connected via a common node (i.e., a shared connection point) to the first and second transistors TX1 and TX2.

The pixel transistors may include a reset transistor RX, a source follower transistor SF, a selection transistor SEL, and a dual conversion gain transistor DCX. In some embodiments, each unit pixel P is illustrated as including four pixel transistors, however, example embodiments of the inventive concept are not limited thereto, and the number of pixel transistors in each unit pixel may be varied.

In detail, the first and second photoelectric conversion elements PD1 and PD2 may generate and accumulate charges corresponding to incident light. The first and second photoelectric conversion elements PD1 and PD2 may be, for example, a photo diode, a photo transistor, a photo gate, a pinned photo diode (PPD), and/or a combination thereof.

The first and second transfer transistors TX1 and TX2 transfer charges accumulated in the first and second photoelectric conversion elements PD1 and PD2 to the floating diffusion region FD. The first and second transfer transistors TX1 and TX2 may be controlled by first and second transfer signals TG1 and TG2. The first and second transfer transistors TX1 and TX2 may share the floating diffusion region FD.

The floating diffusion region FD receives charges generated in the first or second photoelectric conversion element PD1 or PD2 and cumulatively stores the charges. The source follower transistor SF may be controlled according to an amount of photocharges accumulated in the floating diffusion region FD.

The reset transistor RX may periodically reset the charges accumulated in the floating diffusion region FD according to a reset signal applied to a reset gate electrode RG. In detail, a drain terminal of the reset transistor RX may be connected to the dual conversion gain transistor DCX, and a source terminal may be connected to a pixel power supply voltage VPIX. When the reset transistor RX and the dual conversion gain transistor DCX are turned on, the pixel power supply voltage VPIX may be transferred to the floating diffusion region FD. Accordingly, the charges accumulated in the floating diffusion region FD may be discharged, thus resetting the floating diffusion region FD.

The dual conversion gain transistor DCX may be connected between the floating diffusion region FD and the reset transistor RX. The dual conversion gain transistor DCX may be connected in series to the reset transistor RX. The dual conversion gain transistor DCX may change a conversion gain of the unit pixel P by changing a capacitance of the floating diffusion region FD in response to a dual conversion gain control signal.

In detail, when capturing an image, high illuminance light and low illuminance light may be simultaneously incident on a pixel array, or strong light and weak light may be simultaneously incident on a pixel array. Accordingly, each pixel may have a conversion gain that varies according to incident light. That is, the unit pixel P may have a first conversion gain when the dual conversion gain transistor DCX is turned off, and may have a second conversion gain greater than the first conversion gain when the dual conversion gain transistor DCX is turned on. That is, different conversion gains may be provided in a first conversion gain mode (i.e., a high illuminance mode) and a second conversion gain mode (i.e., a low illuminance mode) according to operation of the dual conversion gain transistor DCX.

When the dual conversion gain transistor DCX is turned off, the capacitance of the floating diffusion region FD may be a first capacitance. When the dual conversion gain transistor DCX is turned on, the capacitance of the floating diffusion region FD may be a second capacitance higher than the first capacitance. The capacitance of the floating diffusion region FD may increase and thus the conversion gain may decrease when the dual conversion gain transistor DCX is turned on, and the capacitance of the floating diffusion region FD may decrease and thus the conversion gain may increase when the dual conversion gain transistor DCX is turned off.

The source follower transistor SF may be a source follower buffer amplifier, which generates a source-drain current in proportion to the amount of charges in the floating diffusion region FD input to a source follower gate electrode. The source follower transistor SF amplifies a potential change in the floating diffusion region FD, and outputs an amplified signal to an output line Vout through the selection transistor SEL. A source terminal of the source follower transistor SF may be connected to the pixel power supply voltage VPIX, and a drain terminal of the source follower transistor SF may be connected to a source terminal of the selection transistor SEL.

The selection transistor SEL may select the unit pixels P to be read in units of rows. When the selection transistor SEL is turned on in response to a selection signal SG applied to a selection gate electrode, an electric signal output to a drain electrode of the source follower transistor SF may be output to the output line Vout.

Referring to FIG. 2B, the unit pixel P may include first, second, third, and fourth photoelectric conversion elements PD1, PD2, PD3, and PD4, first, second, third, and fourth transfer transistors TX1, TX2, TX3, and TX4, and the floating diffusion region FD. Furthermore, the unit pixel P may include four pixel transistors RX, DCX, SF, and SEL as illustrated in the embodiment of FIG. 2A.

The first, second, third, and fourth transfer transistors TX1, TX2, TX3, and TX4 may share one floating diffusion region FD. Transfer gate electrodes of the first, second, third, and fourth transfer transistors TX1, TX2, TX3, and TX4 may be respectively controlled by first, second, third, and fourth transfer signals TG1, TG2, TG3, and TG4.

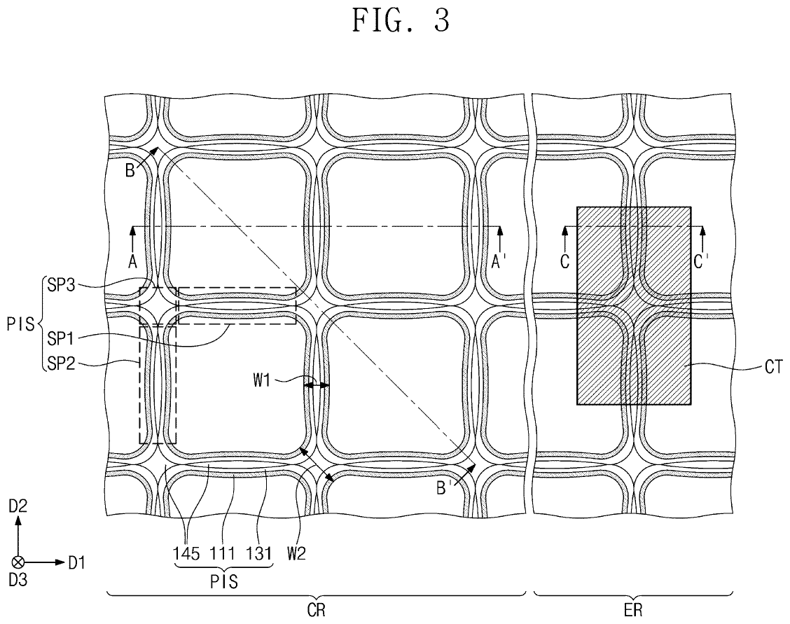

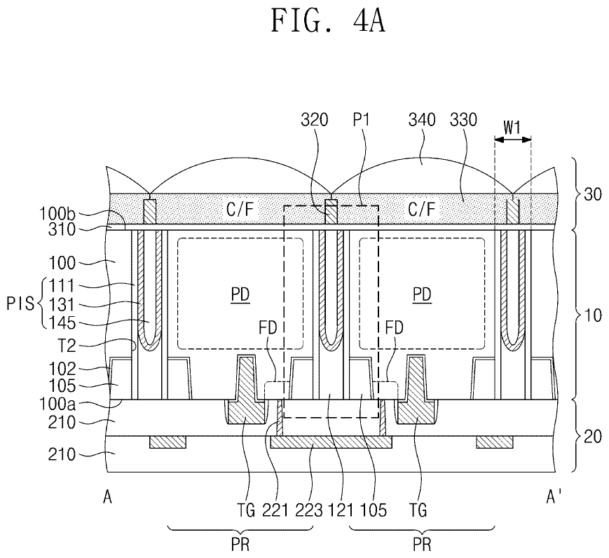

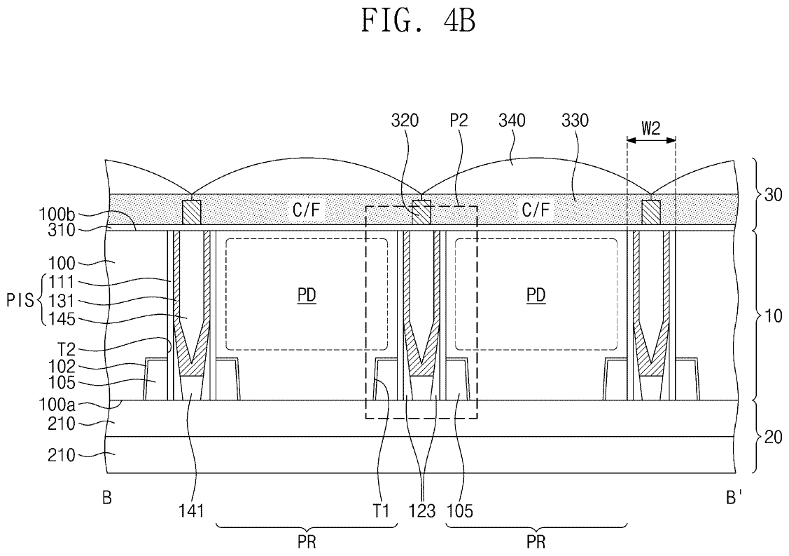

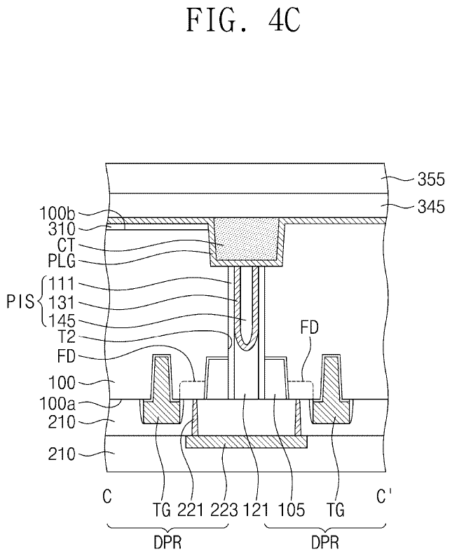

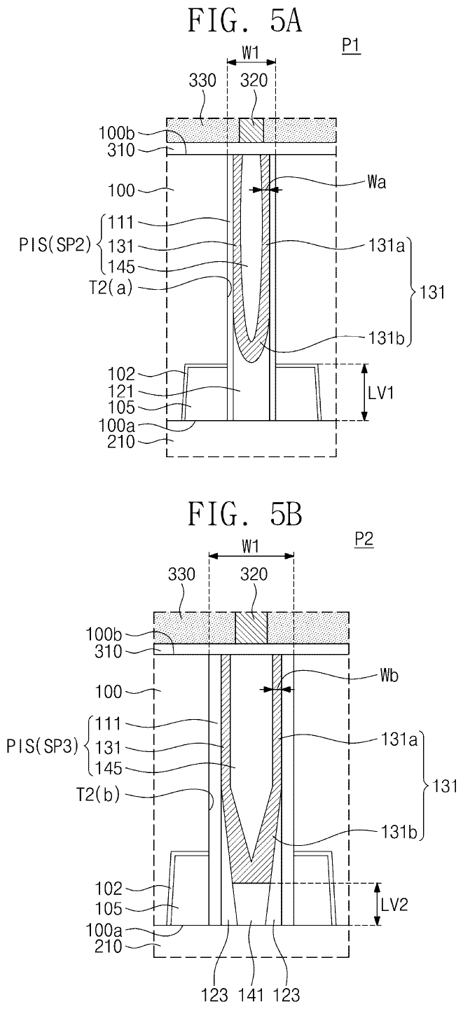

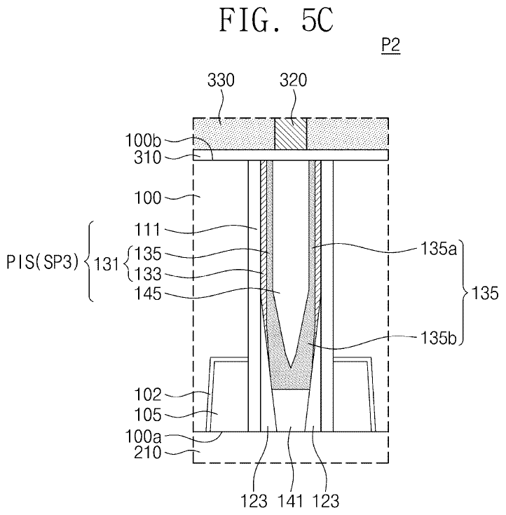

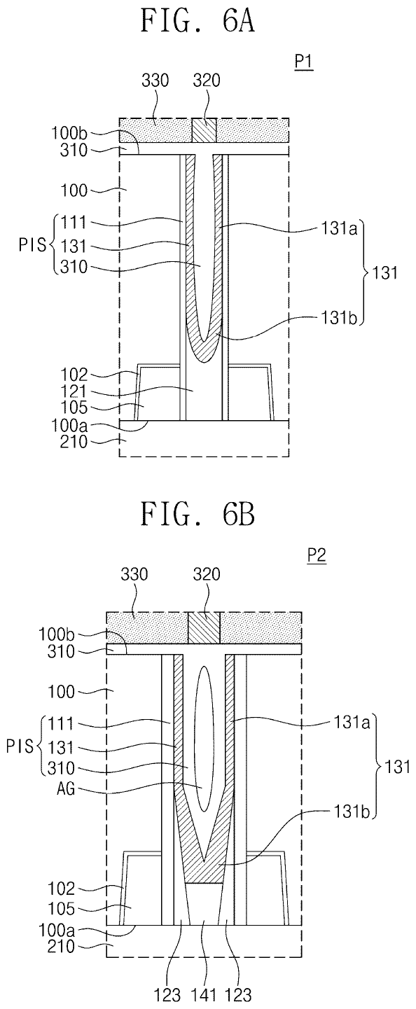

FIG. 3 is a plan view of a portion of an image sensor according to embodiments of the inventive concept. FIGS. 4A, 4B, and 4C are cross-sectional views of an image sensor, taken along line A-A′, line B-B′, and line C-C′ of FIG. 3, respectively, according to embodiments of the inventive concept. FIGS. 5A and 6A are enlarged views of portion P1 of FIG. 4A. FIGS. 5B, 5C, and 6B are enlarged views of portion P2 of FIG. 4B.

Referring to FIGS. 3, 4A, 4B, and 4C, an image sensor according to embodiments of the inventive concept may include a photoelectric conversion layer 10, a read-out circuit layer 20, and a light transmissive layer 30 in a vertical view.

The photoelectric conversion layer 10 may be disposed between the read-out circuit layer 20 and the light transmissive layer 30 in a vertical view (i.e., a vertical cross-section or side view). Externally incident light may be converted into an electric signal in the photoelectric conversion layer 10. The photoelectric conversion layer 10 may include a semiconductor substrate 100, a pixel isolation structure PIS, and photoelectric conversion regions PD.

In detail, the semiconductor substrate 100 may have a first surface 100a (i.e., a front surface) and a second surface 100b (i.e., a back surface) opposing (i.e., opposite) each other. The semiconductor substrate 100 may be a substrate in which a first-conductive type (e.g., p-type) epitaxial layer is formed on a first-conductive type bulk silicon substrate, and may be a substrate in which a bulk silicon substrate has been removed and only a p-type epitaxial layer remains during a manufacturing process of an image sensor. Alternatively, the semiconductor substrate 100 may be a bulk semiconductor substrate including a first-conductive type well.

The semiconductor substrate 100 may include a center region CR and an edge region ER around the center region CR. The center region CR may include a plurality of pixel regions PR defined by the pixel isolation structure PIS, and the edge region ER may include a plurality of dummy pixel regions DPR defined by the pixel isolation structure PIS. The pixel regions PR and the dummy pixel regions DPR may be two-dimensionally arranged along a first direction D1 and a second direction D2 that intersects the first direction D1. The first direction D1 and the second direction D2 may be parallel with the first surface 100a and the second surface 100b of the semiconductor substrate 100.

A device isolation film 105 may be arranged adjacent to the first surface 100a of the semiconductor substrate 100 in each of the pixel regions PR and the dummy pixel regions DPR. The device isolation film 105 may define active portions in the first surface 100a of the semiconductor substrate 100.

The device isolation film 105 may be provided in a first trench T1 formed by recessing the first surface 100a of the semiconductor substrate 100. The device isolation film 105 may be formed of an insulating material such as silicon oxide. An insulating liner film 101 may be interposed between the device isolation film 105 and the first trench T1. The insulating liner film 101 may have a substantially uniform thickness. The insulating liner film 101 may include a liner oxide film and a liner nitride film sequentially stacked.

The pixel isolation structure PIS may vertically penetrate (i.e., may vertically extend into) the semiconductor substrate 100. The pixel isolation structure PIS may be provided in a second trench T2 formed in the semiconductor substrate 100. The pixel isolation structure PIS may penetrate a portion of the device isolation film 105. The pixel isolation structure PIS may have an aspect ratio approximately within the range of 10:1 to 100:1.

The pixel isolation structure PIS may include first isolation portions SP1 extending side by side (i.e., extending adjacent to each other) along the first direction D1, second isolation portions SP2 extending side by side (i.e., extending adjacent to each other) across the first isolation portions SP1 along the second direction D2 that intersects the first direction D1, and third isolation portions SP3 provided at intersections of the first isolation portions SP1 and the second isolation portions SP2. Here, the first direction D1 and the second direction D2 may be parallel with the first surface 100a of the semiconductor substrate 100. Each of the first and second isolation portions SP1 and SP2 of the pixel isolation structure PIS may have a first width W1, and each of the third isolation portions SP3 of the pixel isolation structure PIS may have a second width W2 that is greater than the first width W1 and is in a diagonal direction with respect to the first and second directions D1 and D2.

The pixel isolation structure PIS may have an upper width at the first surface 100a of the semiconductor substrate 100 and a lower width at a bottom surface thereof. The lower width may be smaller than or substantially equal to the upper width. For example, the width of the pixel isolation structure PIS may gradually decrease in a direction from the first surface 100a to the second surface 100b of the semiconductor substrate 100. The pixel isolation structure PIS may have a length in a direction (e.g.., third direction D3) perpendicular to a surface of the semiconductor substrate 100. The length of the pixel isolation structure PIS may be substantially equal to a vertical thickness of the semiconductor substrate 100.

The pixel isolation structure PIS may surround each of the photoelectric conversion regions PD in a plan view. The pixel isolation structure PIS may continuously extend from the center region CR to the edge region ER along the first direction D1 and the second direction D2.

An upper surface of the pixel isolation structure PIS may be substantially coplanar with the first surface 100a of the semiconductor substrate 100. The upper surface of the pixel isolation structure PIS may be substantially coplanar with an upper surface of the device isolation film 105. A lower surface of the pixel isolation structure PIS may be substantially coplanar with the second surface 100b of the semiconductor substrate 100.

As illustrated in FIG. 4C, the pixel isolation structure PIS may be connected to a back contact plug PLG in the edge region ER. For example, the back contact plug PLG may extend into a portion of the pixel isolation structure PIS. In detail, the back contact plug PLG may be electrically connected to a first buried pattern 131 formed of a conductive material in the pixel isolation structure PIS. A negative bias may be applied to the pixel isolation structure PIS through the contact pattern CT and the back contact plug PLG. Accordingly, a dark current generated at a boundary between the pixel isolation structure PIS and the semiconductor substrate 100 may be reduced.

A structure of the pixel isolation structure PIS according to embodiments will be described in more detail with reference to FIGS. 5A, 5B, 5C, 6A, and 6B.

Furthermore, a barrier region (not shown) adjacent to a sidewall of the pixel isolation structure PIS and including impurities may be provided in the semiconductor substrate 100. When forming a deep trench by patterning the semiconductor substrate 100, the barrier region may reduce a dark current that is generated by an electron-hole pair (EHP) formed due to a surface defect of the deep trench. The barrier region may include impurities of the same conductive type (e.g., p-type) as the semiconductor substrate 100. An impurity doping concentration in the barrier region may be higher than an impurity doping concentration in the semiconductor substrate 100.

The photoelectric conversion regions PD may be provided in the semiconductor substrate 100 of each of the pixel regions PR. The photoelectric conversion regions PD may generate photocharges in proportion to an intensity of incident light. The photoelectric conversion regions PD may be formed by ion injecting, into the semiconductor substrate 100, impurities of a second-conductive type (e.g., n-type) that is opposite to the conductive type of the semiconductor substrate 100. The photoelectric conversion region PD of the second-conductive type (i.e., second conductivity type) may constitute a photodiode through a junction with the semiconductor substrate 100 of the first-conductive type (i.e., first conductivity type).

According to some embodiments, the photoelectric conversion regions PD may have an impurity concentration difference between a region adjacent to the first surface 100a and a region adjacent to the second surface 100b so as to have a potential gradient between the first surface 100a and the second surface 100b of the semiconductor substrate 100. For example, the photoelectric conversion regions PD may also include a plurality of impurity regions stacked vertically.

The read-out circuit layer 20 may be disposed on the first surface 100a of the semiconductor substrate 100. The read-out circuit layer 20 may include read-out circuits (e.g., MOS transistors) electrically connected to the photoelectric conversion regions PD. As used herein, the read-out circuits may also be referred to as pixel circuits. Namely, the read-out circuit layer 20 may include the reset transistor RX, the selection transistor SEL, the dual conversion gain transistor DCX, and the source follower transistor SF described above with reference to FIGS. 2A and 2B.

In each of the pixel regions PR, transfer gate electrodes TG may be arranged on an active portion of the semiconductor substrate 100. The transfer gate electrode TG may be located at a center of each of the pixel regions PR in a plan view. A portion of the transfer gate electrode TG may be disposed in the semiconductor substrate 100, and a gate insulating film GIL may be interposed between the transfer gate electrode TG and the semiconductor substrate 100.

The floating diffusion region FD may be provided in an active portion on one side of the transfer gate electrode TG. The floating diffusion region FD may be formed by ion injecting impurities of a type that is opposite to the type of the semiconductor substrate 100. For example, the floating diffusion region FD may be an n-type impurity region.

In each of the pixel regions PR, at least one pixel transistor may be provided to an active portion. The pixel transistor provided in each of the pixel regions PR may be at least one of the reset transistor RX, the source follower transistor SF, the dual conversion gain transistor DCX, and/or the selection transistor SEL described above with reference to FIGS. 2A and 2B.

The pixel transistor may include a pixel gate electrode (not shown) traversing the active portion and source/drain regions (not shown) provided in the active portion on two sides of the pixel gate electrode. The source/drain regions of the pixel transistor may include impurities of the second-conductive type. For example, the source/drain regions may include n-type impurities.

Interlayer insulating layers 210 may cover the transfer gate electrode TG on the first surface 100a of the semiconductor substrate 100. As used herein, “an element A covers an element B” (or similar language) means that the element A is on the element B but does not necessarily mean that the element A covers the element B entirely.

Wiring structures 221 and 223 connected to the read-out circuits may be arranged in the interlayer insulating layers 210. The wiring structures 221 and 223 may include contact plugs 221 penetrating the interlayer insulating layers 210 and connection lines 223 connected to the contact plugs 221.

The light transmissive layer 30 may be disposed on the second surface 100b of the semiconductor substrate 100. The light transmissive layer 30 may include a planarized insulating film 310, a lattice structure 320, color filters 330, and micro lenses 340. The light transmissive layer 30 may concentrate and filter externally incident light and provide the same to the photoelectric conversion layer 10.

In detail, the planarized insulating film 310 may cover the second surface 100b of the semiconductor substrate 100. The planarized insulating film 310 may be formed of a transparent insulating material and may include a plurality of layers. The planarized insulating film 310 may be formed of an insulating material having a refractive index different from that of the semiconductor substrate 100. The planarized insulating film 310 may include, for example, metal oxide such as Al₂O₃, TiO₂, Ta₂O₅, and HfO and/or SiO₂.

The lattice structure 320 may be disposed on the planarized insulating film 310. Similarly to the pixel isolation structure PIS, the lattice structure 320 may have a lattice form in a plan view. The lattice structure 320 may overlap the pixel isolation structure PIS in a plan view. That is, the lattice structure 320 may include first portions extending in the first direction D1 and second portions extending in the second direction D2 across from the first portions. A width of the lattice structure 320 may be substantially equal to or smaller than a minimum width of the pixel isolation structure PIS. As used herein, “an element A overlaps an element B in a direction X” (or similar language) means that there is at least one straight line that extends in the direction X and intersects both the elements A and B.

The lattice structure 320 may include a conductive pattern and/or a low refractive pattern. The light shielding pattern may include, for example, a metal material such as titanium, tantalum, or tungsten. The low refractive pattern may be formed of a material having a lower refractive index than the light shielding pattern. The low refractive pattern may be formed of an organic material and may have a refractive index approximately between 1.1 and 1.3. For example, the lattice structure 320 may be a polymer layer including silica nanoparticles.

The color filters 330 may be formed corresponding to the pixel regions PR, respectively. The color filters 330 may fill a space defined by the lattice structure 320. The color filters 330 may include a color filter of red, green, or blue or a color filter of magenta, cyan, or yellow according to a unit pixel.

The micro lenses 340 may be arranged on the color filters 330. The micro lenses 340 may have a convex shape and a predetermined radius of curvature. The micro lenses 340 may be formed of a light transmissive resin.

Hereinafter, a pixel structure of an image sensor according to embodiments of the inventive concept will be described in detail with reference to FIGS. 5A, 5B, 5C, 6A, and 6B.

Referring to FIGS. 5A and 5B, the pixel isolation structure PIS may include a sidewall insulating pattern 111, a first buried pattern 131, and a second buried pattern 145.

The sidewall insulating pattern 111 may be provided between the first buried pattern 131 and the second trench T2 of the semiconductor substrate 100. The sidewall insulating pattern 111 may surround each pixel region PR and each dummy pixel region DPR in a plan view. The sidewall insulating pattern 111 may be in direct contact with the semiconductor substrate 100. The sidewall insulating pattern 111 may include a material having a lower refractive index than the semiconductor substrate 100. The sidewall insulating pattern 111 may include, for example, a silicon-based insulating material (e.g., silicon nitride, silicon oxide, and/or silicon oxynitride) and/or a high-k material (e.g., hafnium oxide and/or aluminum oxide). For example, the sidewall insulating pattern 111 may include a plurality of layers, which may include different materials.

The first buried pattern 131 may be disposed on the sidewall insulating pattern 111 in the second trench T2. The first buried pattern 131 may cover a portion of the sidewall insulating pattern 111 with a uniform thickness. The first buried pattern 131 may surround each pixel region PR and each dummy pixel region DPR in a plan view.

In the first, second, and third isolation portions SP1, SP2, and SP3 (FIG. 3) of the pixel isolation structure PIS, the first buried pattern 131 may include sidewall portions 131a on the sidewall insulating pattern 111 and a connection portion 131b connecting (e.g., extending between) the sidewall portions 131a. The connection portion 131b may be disposed closer to the first surface 100a of the semiconductor substrate 100 than to the second surface 100b.

The connection portion 131b of the first buried pattern 131 may be vertically spaced apart from the first surface 100a of the semiconductor substrate 100. A bottom surface of the first buried pattern 131 may be adjacent to the second surface 100b of the semiconductor substrate 100.

In the first and second isolation portions SP1 and SP2 (FIG. 3) of the pixel isolation structure PIS, the connection portion 131b of the first buried pattern 131 may have a curved surface that is convex toward the first surface 100a of the semiconductor substrate 100. That is, in the first and second isolation portions SP1 and SP2 (FIG. 3) of the pixel isolation structure PIS, the first buried pattern 131 may have an arch-shaped cross-section. In the third isolation portion SP3 (FIG. 3) of the pixel isolation structure PIS, the connection portion 131b of the first buried pattern 131 may have a flat upper surface. In other words, in the third isolation portion SP3, the connection portion 131b of the first buried pattern 131 may have a flat surface that faces the first surface 100a of the semiconductor substrate 100.

The sidewall portion 131a of the first buried pattern 131 may have a first thickness Wa in the first and second isolation portions SP1 and SP2 (FIG. 3) and a second thickness Wb that is larger than the first thickness Wa in the third isolation portion SP3.

In the first and second isolation portions SP1 and SP2 (FIG. 3) of the pixel isolation structure PIS, the connection portion 131b of the first buried pattern 131 may be spaced a first distance LV1 apart from the first surface 100a of the semiconductor substrate 100. In the third isolation portion SP3 of the pixel isolation structure PIS, the connection portion 131b of the first buried pattern 131 may be spaced a second distance LV2 apart from the first surface 100a of the semiconductor substrate 100, and the second distance LV2 may be less than the first distance LV1.

In the first and second isolation portions SP1 and SP2 (FIG. 3) of the pixel isolation structure PIS, the connection portion 131b of the first buried pattern 131 may be spaced farther from the first surface 100a than from a lower surface of the device isolation film 105. In the third isolation portion SP3 of the pixel isolation structure PIS, a distance between the connection portion 131b of the first buried pattern 131 and the first surface 100a of the semiconductor substrate 100 may be less than a distance between the first surface 100a of the semiconductor substrate 100 and the lower surface of the device isolation film 105.

According to some embodiments, the first buried pattern 131 may be a conductive pattern including a conductive material. For example, the first buried pattern 131 may include a semiconductor material doped with impurities. The impurities in the first buried pattern 131 may have a first-conductive type that is the same as the conductive type of the semiconductor substrate 100. The impurities in the first buried pattern 131 may include, for example, at least one of boron (B), phosphorus (P), arsenic (As), gallium (Ga), indium (In), antimony (Sb), and/or aluminum (Al). The concentration of first-conductive type impurities in the first buried pattern 131 may be approximately 1.0e¹⁸ to 2.0e²² atoms/cm². The first buried pattern 131 may include a polysilicon film doped with first-conductive type impurities. In some embodiments, the first buried pattern 131 may include a metal material, an organic/inorganic conductive material, or the like instead of a semiconductor material doped with first-conductive type impurities.

Referring to FIG. 5C, the first buried pattern 131 may include a conductive pattern 133 on the sidewall insulating pattern 111 and a buried semiconductor pattern 135 on the conductive pattern 133. The conductive pattern 133 may include a semiconductor material doped with first-conductive type impurities, and the buried semiconductor pattern 135 may include a semiconductor material undoped with impurities or a semiconductor material doped with impurities. When the buried semiconductor pattern 135 includes a semiconductor material doped with first-conductive type impurities, an impurity concentration in the buried semiconductor pattern 135 may be lower than an impurity concentration in the conductive pattern 133. The concentration of first-conductive type impurities in the conductive pattern 133 may be approximately 1.0e¹⁸ to 2.0e²² atoms/cm². Furthermore, the conductive pattern 133 may include a polycrystalline semiconductor material, and the buried semiconductor pattern 135 may include an amorphous semiconductor material.

The conductive pattern 133 may include separated portions in the third isolation portion SP3 (i.e., an intersection region of the second trench T2). Furthermore, in the third isolation portion of the pixel isolation structure PIS, upper portions of the sidewall portions of the conductive pattern 131 may have a thickness that decreases in a direction toward the first surface 100a of the semiconductor substrate 100. That is, the upper portions of the sidewall portions of the conductive pattern 131 may have a tapered spacer shape.

The buried semiconductor pattern 135 may be provided between the separated portions of the conductive pattern 133. The buried semiconductor pattern 135 may include sidewall portions 135a on the conductive pattern 133 and a connection portion 135b connecting the sidewall portions 135a.

In the embodiment illustrated in FIG. 5C, sidewall portions of the first buried pattern 131 may be formed by a portion of the buried semiconductor pattern 135 and the conductive pattern 133, and a connection portion of the first buried pattern 131 may be formed by a portion of the buried semiconductor pattern 135.

A gap region may be defined by the sidewall portions 131a and the connection portion 131b of the first buried pattern 131 in the second trench T2, and the second buried pattern 145 may be disposed in the gap region defined by the first buried pattern 131. For example, the second buried pattern 145 may be on the first buried pattern 131.

For example, the second buried pattern 145 may be an air gap or void surrounded by the first buried pattern 131 and the planarized insulating film 310. As another example, the second buried pattern 145 may include at least one of a silicon oxide film, a silicon oxynitride film, a silicon nitride film, and/or metal oxide. The second buried pattern 145 may include the same insulating material as the planarized insulating film 310.

A first buried insulating pattern 141 may be provided on the third isolation portion SP3 of the pixel isolation structure PIS and disposed on a flat upper surface of the connection portion 131b of the first buried pattern 131. The first buried insulating pattern 141 may have an upper surface that is substantially coplanar with the first surface 100a of the semiconductor substrate 100. The first buried insulating pattern 141 may include, for example, at least one of a silicon oxide film, a silicon oxynitride film, and/or a silicon nitride film.

According to embodiments, supporter patterns 121 and 123 may be arranged on the pixel isolation structure PIS in the second trench T2, as illustrated in FIGS. 5A, 5B, and 5C. The supporter patterns 121 and 123 may be adjacent to the device isolation film 105 and have an upper surface that is substantially coplanar with the first surface 100a of the semiconductor substrate 100. For example, the supporter patterns 121 and 123 may be on the first buried pattern 131.

The supporter patterns 121 and 123 may include, for example, a silicon-based insulating material (e.g., silicon nitride, silicon oxide, and/or silicon oxynitride) and/or a high-k material (e.g., hafnium oxide and/or aluminum oxide).

The supporter patterns may include a first pattern part 121 disposed in the second trench T2 and provided on the first and second isolation portions SP1 and SP2 of the pixel isolation structure PIS and second pattern parts 123 arranged in the second trench T2 and provided on the third isolation portion SP3 of the pixel isolation structure PIS. The first pattern part 121 of the supporter patterns may be in contact with a curved surface of the connection portion 131b of the first buried pattern 131, and the second pattern parts 123 may be interposed between the sidewall insulating pattern 111 and a portion of the first buried pattern 131. Furthermore, the second pattern parts 123 may be interposed between the sidewall insulating pattern 111 and the first buried insulating pattern 141. The second patterns parts 123 may have an inclined surface, and widths of the second pattern parts 123 may increase in a direction toward the first surface 100a.

In the first and second isolation portions SP1 and SP2 of the pixel isolation structure PIS, the first pattern part 121 of the supporter patterns may be in contact with the connection portion 131b of the first buried pattern 131. In the third isolation portion SP3 of the pixel isolation structure PIS, the inclined surfaces of the second pattern parts 123 of the supporter patterns may be in contact with the first buried insulating pattern 141.

Referring to FIGS. 6A and 6B, the planarized insulating film 310 may fill the gap region defined by the first buried pattern 131 in the second trench T2. In this case, the planarized insulating film 310 may extend to the second surface 100b of the semiconductor substrate 100 while fully or partially filling the gap region defined by the first buried pattern 131 in the first and second isolation portions SP1 and SP2 of the pixel isolation structure PIS. Furthermore, in the third isolation portion SP3 of the pixel isolation structure PIS, the planarized insulating film 310 may have an air gap AG defined by the first buried pattern 131.

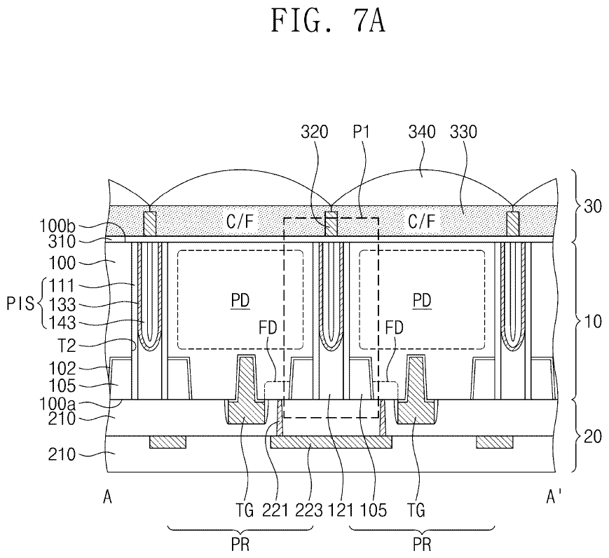

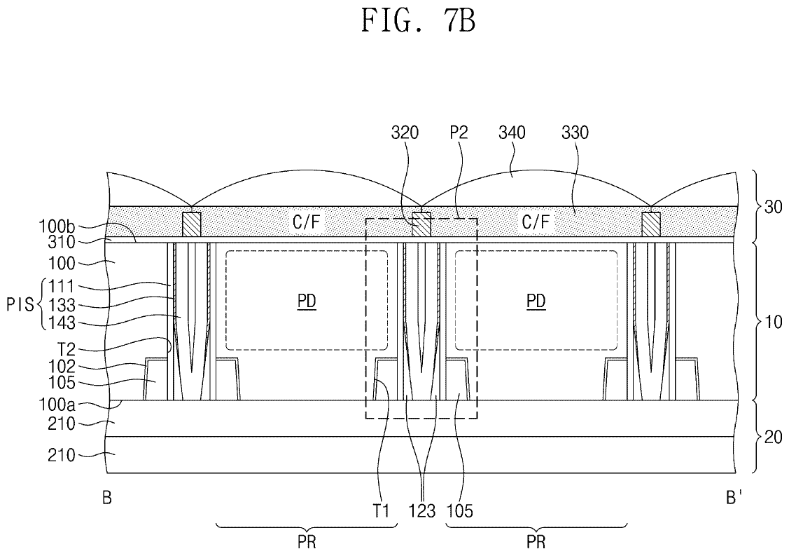

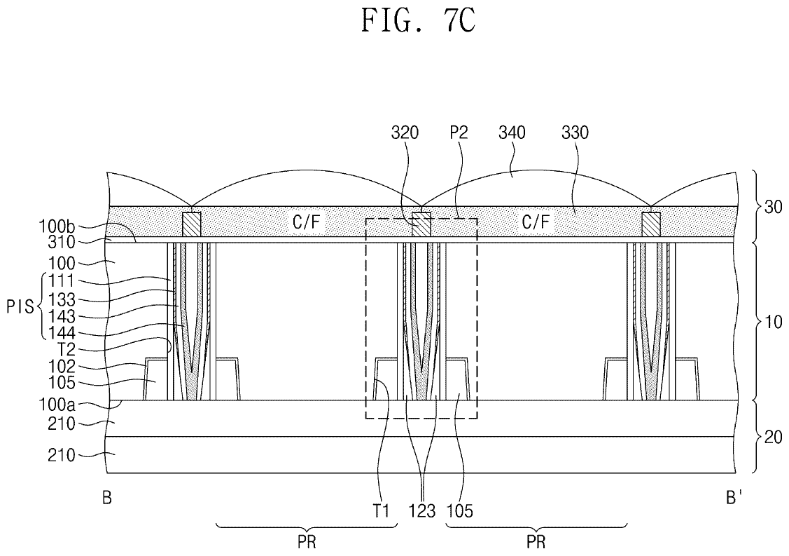

FIG. 7A is a cross-sectional view of an image sensor, taken along line A-A′ of FIG. 3, according to embodiments of the inventive concept. FIGS. 7B and 7C are cross-sectional views of an image sensor, taken along line B-B′ of FIG. 3, according to embodiments of the inventive concept.

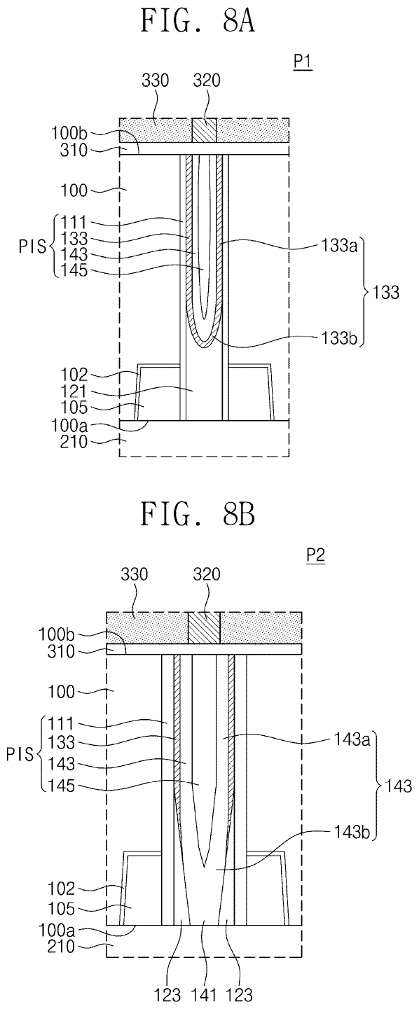

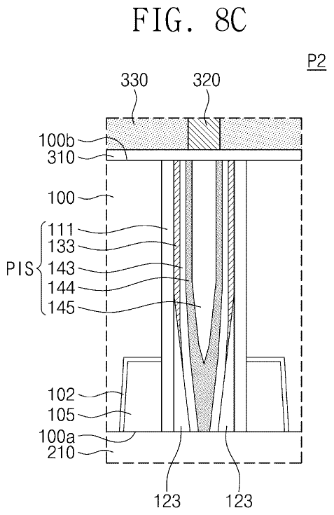

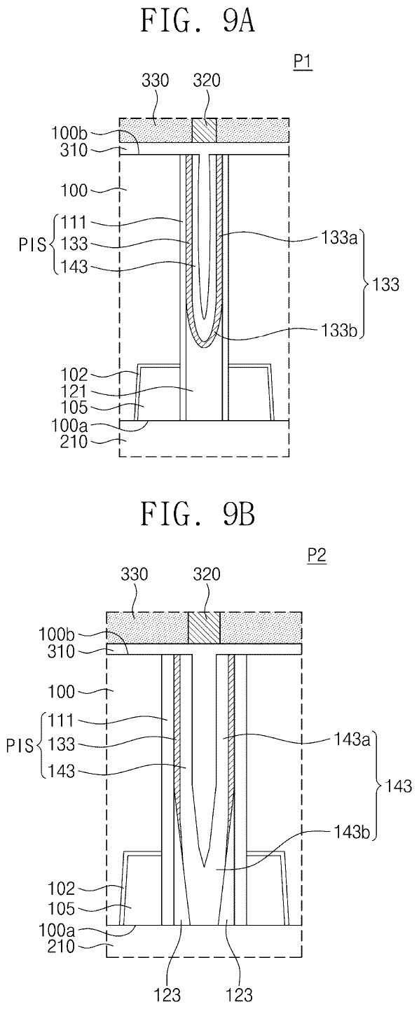

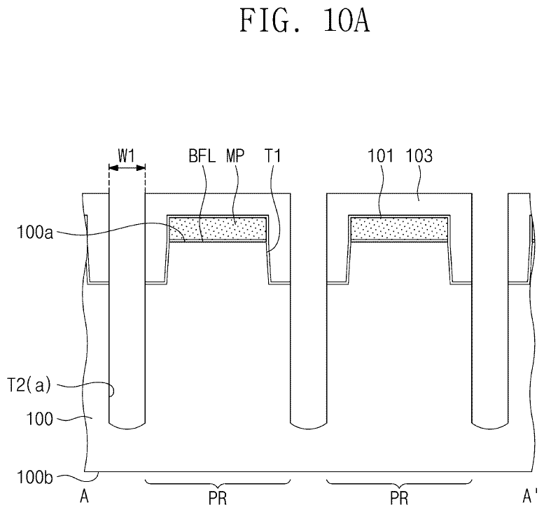

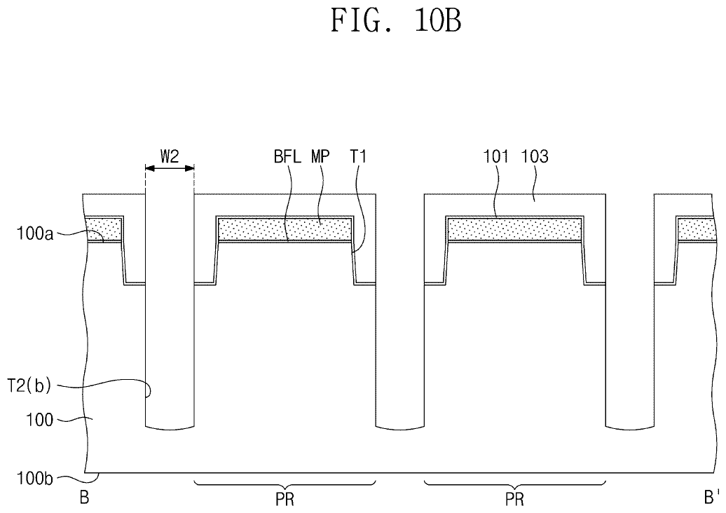

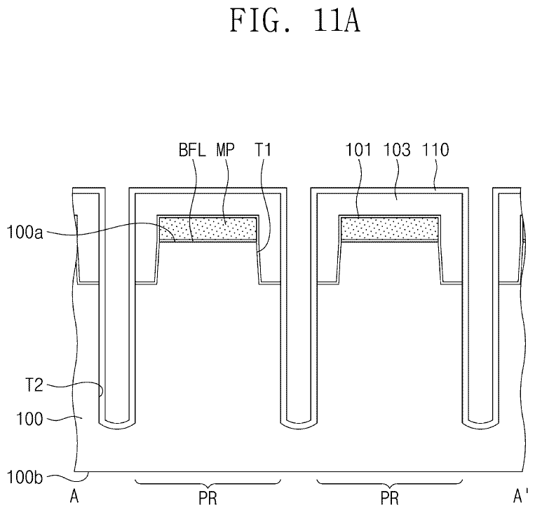

FIGS. 8A and 9A are enlarged views of portion P1 of FIG. 7A illustrating an image sensor according to embodiments of the inventive concept. FIGS. 8B and 9B are enlarged views of portion P2 of FIG. 7B illustrating an image sensor according to embodiments of the inventive concept. FIG. 8C is an enlarged view of portion P2 of FIG. 7C illustrating an image sensor according to embodiments of the inventive concept.

In the embodiments illustrated in FIGS. 7A, 7B, and 7C, the same reference numerals as those illustrated in FIGS. 4A, 4B, 4C, 5A, 5B, 5C, 6A, and 6B refer to the same components, and descriptions thereof may not be provided.

Referring to FIGS. 7A, 7B, and 7C, the pixel isolation structure PIS may include the conductive pattern 133 on the sidewall insulating pattern 111, a second buried insulating pattern 143 on the conductive pattern 133, and the second buried pattern 145 (see FIGS. 8A to 8C) on the second buried insulating pattern 143. For example, a first buried pattern of the pixel isolation structure PIS (e.g., see the first buried pattern 131 in FIGS. 3 and 4A to 4C) may include the conductive pattern 133 and the second buried insulating pattern 143. The conductive pattern 133 may surround each pixel region PR or photoelectric conversion region PD in a plan view.

Referring to FIGS. 8A and 8B, in the first and second isolation portions SP1 and SP of the pixel isolation structure PIS, the conductive pattern 133 may include sidewall portions 133a on the sidewall insulating pattern 111 and a connection portion 133b connecting the sidewall portions 133a.

The connection portion 113b may have a curved surface that is convex toward the first surface 100a of the semiconductor substrate 100 in the first and second isolation portions SP1 and SP of the pixel isolation structure PIS, and the sidewall portions 133a of the conductive pattern 133 may be spaced apart from each other. In the third isolation portion SP3, the sidewall portions 133a may have a thickness that decreases in a direction toward the first surface 100a of the semiconductor substrate 100. That is, the upper portions of the sidewall portions of the conductive pattern 133 may have a tapered spacer shape.

The second buried insulating pattern 143 may have a uniform thickness on the conductive pattern 133 and may not fully fill the second trench T2. The second buried insulating pattern 143 may have an air gap therein. For example, the second buried insulating pattern 143 may be between the conductive pattern 133 and the second buried pattern 145.

In the first, second, and third isolation portions SP1, SP2, and SP3 (FIG. 3) of the pixel isolation structure PIS, the second buried insulating pattern 143 may include sidewall portions 143a and a connection portion 143b. The connection portion 143b may be disposed closer to the first surface 100a of the semiconductor substrate 100 than to the second surface 100b.

In the first and second isolation portions SP1 and SP2 of the pixel isolation structure PIS, the second buried insulating pattern 143 may be provided in a gap region in the conductive pattern 133. In the third isolation portion SP3 of the pixel isolation structure PIS, the sidewall portions 143a of the second buried insulating pattern 143 may be in contact with the sidewall portions of the conductive pattern 133, and the connection portion 143b of the second buried insulating pattern 143 may have a flat upper surface that is substantially coplanar with the first surface 100a of the semiconductor substrate 100. The second buried insulating pattern 143 may include, for example, at least one of a silicon oxide film, a silicon oxynitride film, and/or a silicon nitride film.

Furthermore, the pixel isolation structure PIS may include the second buried pattern 145 provided in a gap region defined in the second buried insulating pattern 143. The second buried pattern 145 may be an air gap or void. As another example, the second buried pattern 145 may include at least one of a silicon oxide film, a silicon oxynitride film, a silicon nitride film, and/or metal oxide.

According to some embodiments, as described above, the supporter patterns 121 and 123 that are adjacent to the first surface 100a of the semiconductor substrate 100 may be provided in the second trench T2. The supporter patterns may include a first pattern part 121 disposed in the second trench T2 and provided on the first and second isolation portions SP1 and SP2 of the pixel isolation structure PIS and second pattern parts 123 arranged in the second trench T2 and provided on the third isolation portion SP3 of the pixel isolation structure PIS. The first pattern part 121 may be in contact with a rounded, curved surface of the conductive pattern 133, and the second pattern parts 123 may be interposed between the sidewall insulating pattern 111 and a portion of the second buried insulating pattern 143. As described above, the second patterns parts 123 may have an inclined surface, and widths of the second pattern parts 123 may increase in a direction to the first surface 100a.

Referring to FIG. 8C, the pixel isolation structure PIS may include the conductive pattern 133 on the sidewall insulating pattern 111, the second buried insulating pattern 143 on the conductive pattern 133, and a buried semiconductor pattern 144 on the second buried insulating pattern 143.

When the second buried insulating pattern 143 does not fill a space between the second pattern parts of the supporter patterns, the buried semiconductor pattern 144 may be provided on the second buried insulating pattern 143. The buried semiconductor pattern 144 may include a semiconductor material doped or undoped with impurities. The second buried pattern 145 may be provided in the buried semiconductor pattern 144, and may be an air gap or void.

Referring to FIGS. 9A and 9B, the planarized insulating film 310 may fill the gap region defined by the second buried insulating pattern 143 in the second trench T2. In this case, the planarized insulating film 310 may extend to the second surface 100b of the semiconductor substrate 100 while fully or partially filling the gap region defined by the second buried insulating pattern 143 in the first and second isolation portions SP1 and SP2 of the pixel isolation structure PIS. Furthermore, in the third isolation portion SP3 of the pixel isolation structure PIS, the planarized insulating film 310 may have an air gap AG defined by the second buried insulating pattern 143.

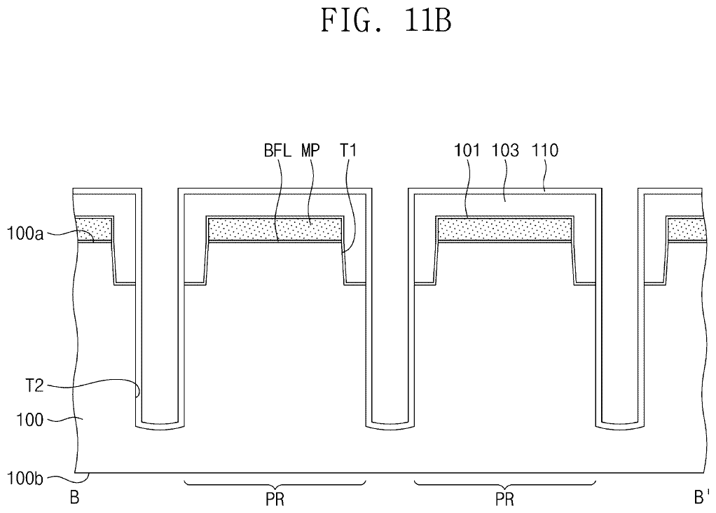

FIGS. 10A, 10B, 11A, 11B, 12A, 12B, 13A, 13B, 14A, 14B, 15A, 15B, 16A, 16B, 17A, 17B, 18A, 18B, 19A, 19B, 20A, and 20B are cross-sectional views taken along line A-A′ and line B-B′ of FIG. 3 illustrating a method for manufacturing an image sensor according to embodiments of the inventive concept. In particular, FIGS. 10A, 11A, 12A, 13A, 14A, 15A, 16A, 17A, 18A, 19A, and 20A are cross-sectional views taken along line A-A′ of FIG. 3. FIGS. 10B, 11B, 12B, 13B, 14B, 15B, 16B, 17B, 18B, 19B, and 20B are cross-sectional views taken along line B-B′ of FIG. 3.

Referring to FIGS. 10A and 10B, the semiconductor substrate 100 of a first-conductive type (e.g., p-type) may be provided. The semiconductor substrate 100 may have the first surface 100a and the second surface 100b opposing each other. The semiconductor substrate 100 may include a first-conductive type epitaxial layer formed on a first-conductive type bulk silicon substrate. Here, the epitaxial layer may be formed by performing selective epitaxial growth (SEG) using the bulk silicon substrate as a seed, and first-conductive type impurities may be doped during an epitaxial growth process. For example, the epitaxial layer may include p-type impurities.

In some embodiments, the semiconductor substrate 100 may be a bulk semiconductor substrate including a first-conductive type well. As another example, the semiconductor substrate 100 may be a silicon-on-insulator (SOI) substrate, a germanium substrate, a germanium-on-insulator (GOI) substrate, or a silicon-germanium substrate.

The first trench T1 may be formed by patterning the first surface 100a of the semiconductor substrate 100. The first trench T1 may define active portions in each of the pixel regions PR. The first trench T1 may be formed by forming a buffer film BFL and a mask pattern MP on the first surface 100a of the semiconductor substrate 100 and anisotropically etching the semiconductor substrate 100 using the mask pattern MP as an etching mask.

The buffer film BFL may be formed by performing a deposition process or thermal oxidation process on the first surface 100a of the semiconductor substrate 100. The buffer film BFL may include a silicon oxide film. The mask pattern MP may include a silicon nitride film or a silicon oxynitride film.

Thereafter, the insulating liner film 101 conformally covering a surface of the first trench T1 may be formed, and a device isolation insulating film 103 filling the first trench T1 in which the insulating liner 101 is formed may be formed. The device isolation insulating film 103 may be formed by thickly depositing an insulating material on the semiconductor substrate 100 in which the first trench T1 is formed. The device isolation insulating film 103 may cover the mask pattern MP while filling the first trench T1.

The insulating liner film 101 may be formed by sequentially depositing a liner oxide film and a liner nitride film. The device isolation insulating film 103 may be formed of, for example, a boron-phosphor silicate glass (BPSG) film, high density plasma (HDP) oxide film, O₃-TEOS film, undoped silicate glass or Tonen SilaZene (TOSZ) material.

The insulating liner film 101 and the device isolation insulating film 103 may be formed using at least one of thin film forming techniques that provide an excellent property of step coverage. The insulating liner film 101 and the device isolation insulating film 103 may be formed by performing a deposition method such as atomic layer deposition (ALD), chemical vapor deposition (CVD), subatmospheric CVD (SACVD), low pressure CVD (LPCVD), plasma enhanced CVD (PECVD), or physical vapor deposition (PVD).

After the device isolation insulating film 103 is formed, the second trench T2 defining the pixel regions PR may be formed in the semiconductor substrate 100. The pixel regions PR may be arranged in a matrix form along the first direction D1 and the second direction D2 intersecting each other and parallel with the first surface 100a of the semiconductor substrate 100.

The second trench T2 may be formed by patterning the device isolation insulating film 103 and the first surface 100a of the semiconductor substrate 100. In detail, the second trench T2 may be formed by forming a second mask pattern (not shown) on the device isolation insulating film 103 and anisotropically etching the device isolation insulating film 103 and the semiconductor substrate 100 using the second mask pattern as an etching mask.

The second trench T2 may vertically penetrate the semiconductor substrate 100 and may partially expose a sidewall of the semiconductor substrate 100. The second trench T2 may be formed deeper than the first trench T1 and may partially penetrate the first trench T1. A bottom surface of the second trench T2 may be spaced apart from the second surface 100b of the semiconductor substrate 100. The second trench T2 may be a deep trench having an aspect ratio approximately between 10:1 and 100:1.

The second trench T2 may include, in a plan view, a plurality of first line regions T2a extending in the first direction D1 and having a first width W1 in the second direction D2 and a plurality of second line regions T2(a) extending in the second direction D2 intersecting the first direction D1 and having the first width W1 in the first direction D1. Furthermore, the second trench T2 may include an intersection region T2(b) where the first line regions and the second line regions T2(a) intersect, and the intersection region T2(b) may have a second width W2 that is greater than the first width W1 in a diagonal direction with respect to the first and second directions D1 and D2.

As the second trench T2 is formed by performing an anisotropic etching process, the second trench T2 may have an inclined sidewall. Alternatively, the trench T2 may have a sidewall that is substantially perpendicular to the first surface 100a of the semiconductor substrate 100.

Referring to FIGS. 11A and 11B, a sidewall insulating film 110 covering an inner wall of the second trench T2 may be formed. The sidewall insulating film 110 may conformally cover the inner wall of the second trench T2 and an upper surface of the device isolation insulating film 103. The sidewall insulating film 110 may be formed using a film-forming technique with an excellent property of step coverage, such as chemical vapor deposition (CVD) or atomic layer deposition (ALD). The sidewall insulating film 110 may include, for example, silicon oxide, silicon nitride, and/or silicon oxynitride. The sidewall insulating pattern 110 may be deposited to a thickness ranging between about 30 Å to about 500 Å, for example.

In some embodiments, after the second trench T2 is formed, a barrier region (not shown) including first-conductive type impurities may be formed along the inner wall of the second trench T2.

For example, the barrier region (not shown) may include impurities of a first-conductive type (e.g., p-type) that is the same as the semiconductor substrate 100. The barrier region may be formed by doping an inside of the second trench T2 with first-conductive type impurities. When forming the barrier region, a beam lined ion implantation process, a plasma doping (PLAD) process, or a gas phase doping (GPD) process, for example, may be performed as a doping process.

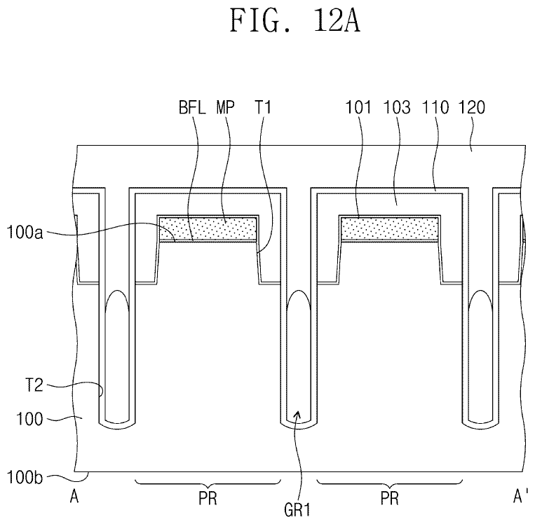

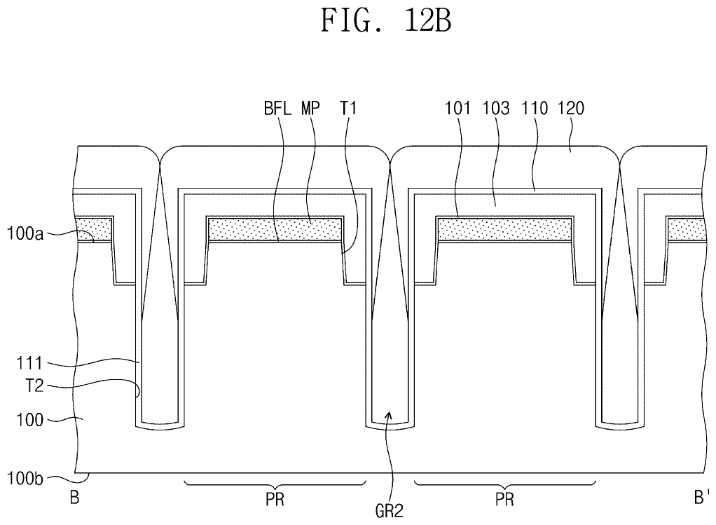

Referring to FIGS. 12A and 12B, a supporter insulating film 120 may be formed on the sidewall insulating film 110.

The supporter insulating film 120 may include, for example, a silicon-based insulating material (e.g., silicon nitride, silicon For example, oxide, and/or silicon oxynitride). The supporter insulating film 120 may be formed using a deposition method with a poor property of step coverage. For example, the supporter insulating film 120 may be formed using an LPCVD-based middle temperature oxidation (MTO) or high temperature oxidation (HTO) method. Alternatively, the supporter insulating film 120 may be formed through a CVD process such as plasma enhanced CVD (PECVD).

Furthermore, the supporter insulating film 120 may be formed using physical vapor deposition or sputtering. Furthermore, the supporter insulating film 120 may be formed using a CVD method with a poor property of step coverage, such as high density plasma (HDP), high aspect ratio process (HARP), and PE-TEOS, or an ALD method with a poor property of step coverage. Monosilane or di-silane may be used when forming the supporter insulating film 120.

Furthermore, before or after the supporter insulating film 120 is formed, an annealing process may be performed to densify the insulating film. For example, the annealing process may be performed at a temperature between 400° C. and 1200° C. using N₂ or O₂ gas. The annealing process may be performed using various methods such as rapid thermal process (RTP), laser spike anneal (LSA), millisecond anneal (MSA), and/or dynamic surface anneal (DSA).

The supporter insulating film 120 may define a first gap region GR1 in the second trench T2 while blocking upper portions of the first and second line regions of the second trench T2 having the first width W1. Furthermore, the supporter insulating film 120 may be deposited to a non-uniform thickness on the sidewall insulating film 110 due to an overhang phenomenon in the intersection region of the second trench T2 having the second width W2 greater than the first width W1. That is, in the intersection region, the supporter insulating film 120 may be deposited to a relatively large thickness at an entrance of the second trench T2 and may be deposited to a relatively small thickness at a sidewall of the second trench T2. Furthermore, the supporter insulating film 120 may not be deposited on a lower portion of the second trench T2 in the intersection region of the second trench T2. In the intersection region of the second trench T2, the supporter insulating film 120 may define a second gap region GR2 while blocking an entrance thereof due to an overhang phenomenon.

In embodiments, the first gap region GR1 and the second gap region GR2 may be defined by the sidewall insulating film 110 and the supporter insulating film 120.

In the first and second line regions, the supporter insulating film 120 in the second trench T2 may have a curved surface that is convex toward the first surface 100a of the semiconductor substrate 100 and defines the first gap region GR1. The curved surface of the supporter insulating film 120 may be positioned at a lower level than the first surface 100a of the semiconductor substrate 100 and a bottom surface of the first trench T1.

In the intersection region, the supporter insulating film 120 in the second trench T2 may have inclined surfaces defining the second gap region GR2. A highest point (i.e., a point where the inclined surfaces of the supporter insulating film 120 meet) of the second gap region GR2 may be positioned at a higher level than the first surface 100a of the semiconductor substrate 100.

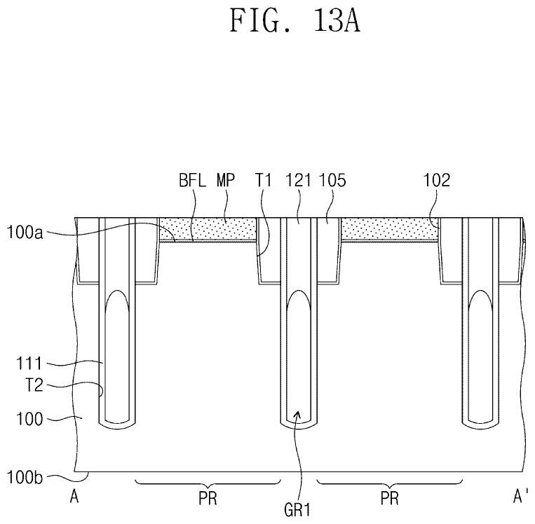

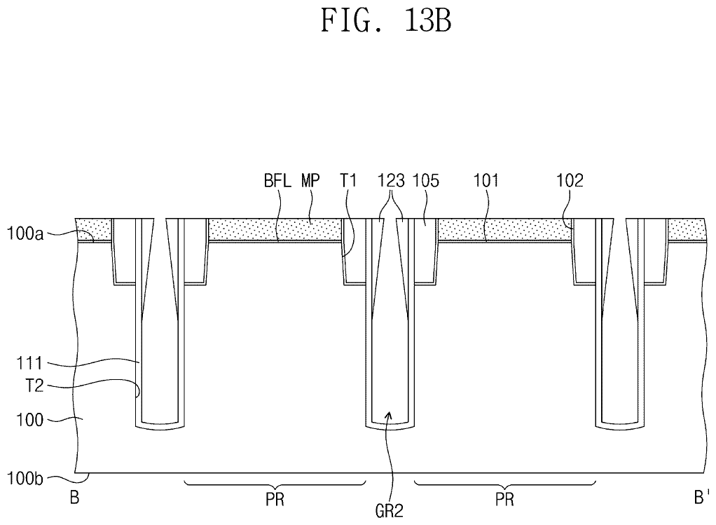

Referring to FIGS. 13A and 13B, a planarized insulating film (not shown) may be formed on the supporter insulating film 120, and, thereafter, a planarization process may be performed on the planarized insulating film, the supporter insulating film 120, and the sidewall insulating film 110 so as to expose an upper surface of the mask pattern MP.

In detail, the planarization process may be performed using a chemical mechanical polishing (CMP) process and an etch-back process. Accordingly, the upper surface of the mask pattern MP may be exposed, and the sidewall insulating pattern 111 and the supporter patterns 121 and 123 may be formed in the second trench T2.

The supporter patterns 121 and 123 may include the first pattern part 121 provided to the first and second line regions of the second trench T2 and the second pattern parts 123 provided to the intersection region of the second trench T2. The second pattern parts 123 of the supporter patterns may have an opening that exposes the second gap region GR2.

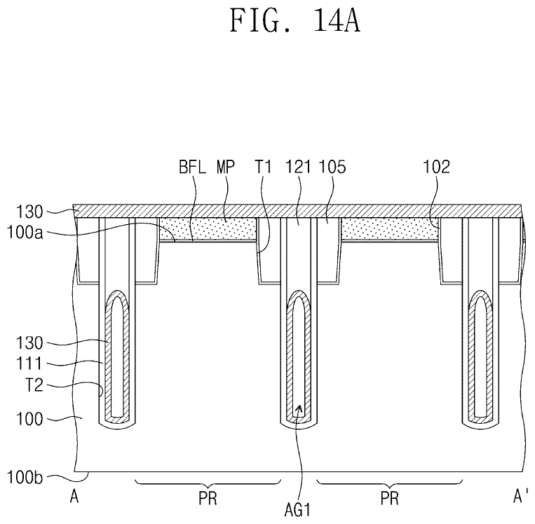

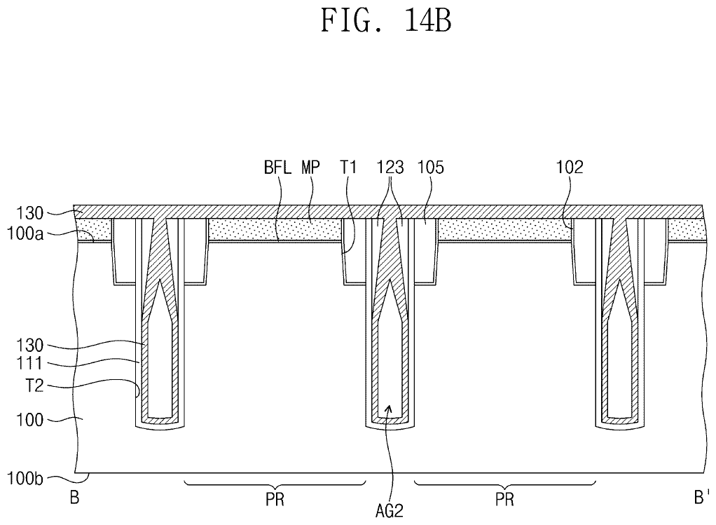

Referring to FIGS. 14A and 14B, after the supporter patterns 121 and 123 are formed in the second trench T2, a conductive liner film 130 may be deposited.

The conductive liner film 130 may be formed by depositing a conductive material using a deposition method with an excellent property of step coverage. The conductive liner film 130 may be deposited using at least one of a low-pressure chemical vapor deposition (LP-CVD), a plasma-enhanced chemical vapor deposition (PE-CVD), and/or an atomic layer deposition (ALD).

According to embodiments, a source gas including first-conductive type impurities may be used when depositing the conductive liner film 130. The source gas may be provided to the first and second line regions of the second trench T2 through the opening formed by the second pattern parts 123 of the supporter patterns in the intersection region of the second trench T2. Accordingly, the conductive liner film 130 may be deposited to a uniform thickness on the sidewall insulating pattern 111 and the supporter patterns 121 and 123 in the second trench T2. The conductive liner film 130 may form a first air gap AG1 in the first and second line regions of the second trench T2. At the same time, the conductive liner film 130 may form a second air gap AG2 in the intersection region of the second trench T2, and the opening formed by the second pattern parts 123 may be closed.

For example, the conductive liner film 130 may be a semiconductor film doped with impurities. When depositing the conductive liner film 130, the source gas may include a first gas including a silane-based compound and a second gas including a compound containing the impurities such as boron (B). The conductive liner film 130 may be deposited through chemical reaction between the first gas and the second gas. The conductive liner film 130 formed in this manner may have a uniform concentration of impurities regardless of a location. The conductive liner film 130 may include polycrystalline silicon or amorphous silicon including first-conductive type impurities. For example, during the deposition process of the conductive liner film 130, SiH (or Si₂H₆) and BCl₃ (or B₂H₆ or PH₃) may be used, and the deposition process may be performed at a low temperature between 300° C. and 530° C.

A silicon seed layer may be formed before the deposition process so that the conductive liner film 130 may be uniformly (conformally or with an excellent property of step coverage) in the second trench T2. For example, diisopropylamino silane (DIPAS) or hexachorodisilane (HCDS) may be used when forming the silicon seed layer.

As another example, the conductive liner film 130 may include a metal material, an organic/inorganic conductive material, or the like instead of a semiconductor material doped with first-conductive type impurities.

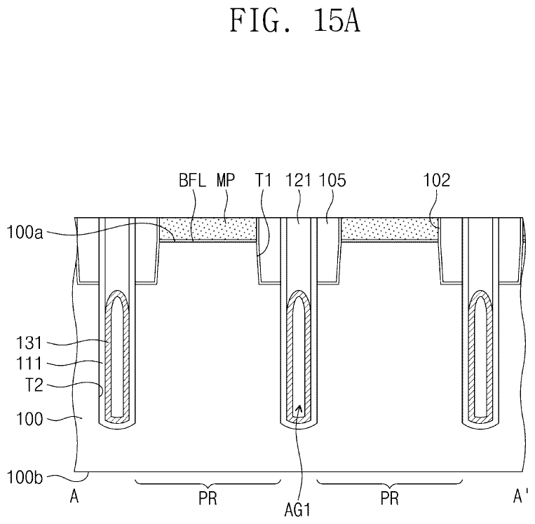

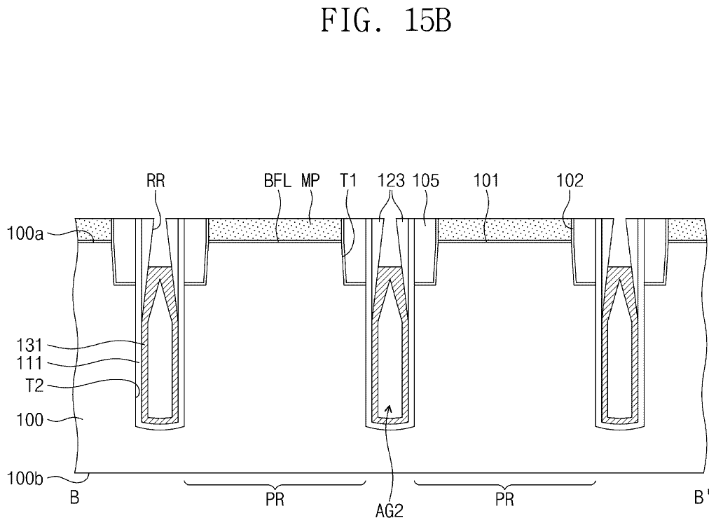

Referring to FIGS. 15A and 15B, an anisotropic etching process (e.g., etch-back process) may be performed on the conductive liner film 130 so as to expose the upper surface of the mask pattern MP. Accordingly, the conductive pattern 131 may be formed in the second trench T2. Furthermore, when performing the anisotropic etching process on the conductive liner film 130, a recess region RR exposing the inclined surfaces of the supporter pattern 123 may be formed through over-etching.

The conductive pattern 131 may have an upper surface positioned at a lower level than the first surface 100a of the semiconductor substrate 100 in the intersection region of the second trench T2. In the intersection region, the upper surface of the conductive pattern 131 may be substantially flat and may be spaced apart from the second air gap AG2. The conductive pattern 131 may completely surround each of the first and second air gaps AG1 and AG2 in the first and second line regions and the intersection region.

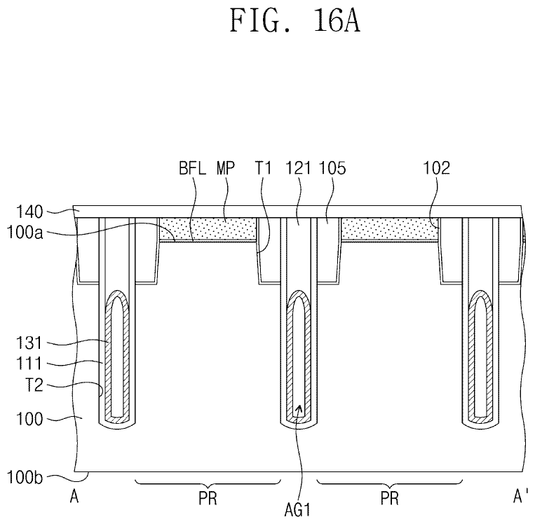

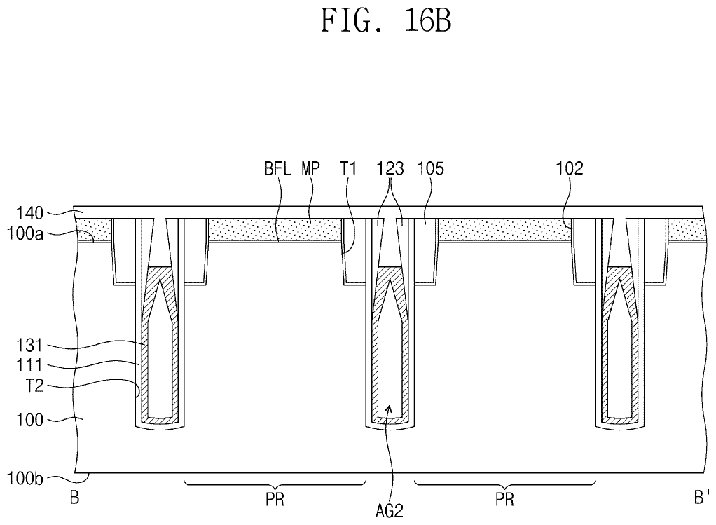

Referring to FIGS. 16A and 16B, a buried insulating film 140 filling the recess region RR may be formed.

The buried insulating film 140 may be formed using a film-forming technique with an excellent property of step coverage, such as chemical vapor deposition (CVD) or atomic layer deposition (ALD). The buried insulating film 140 may include, for example, silicon oxide, silicon nitride, and/or silicon oxynitride. The buried insulating film 140 may include a material such as SiCN, SiOCN, SiBN, and/or SiBCN.

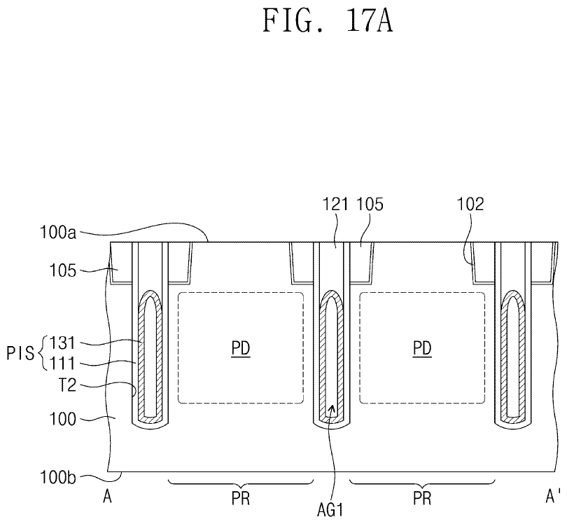

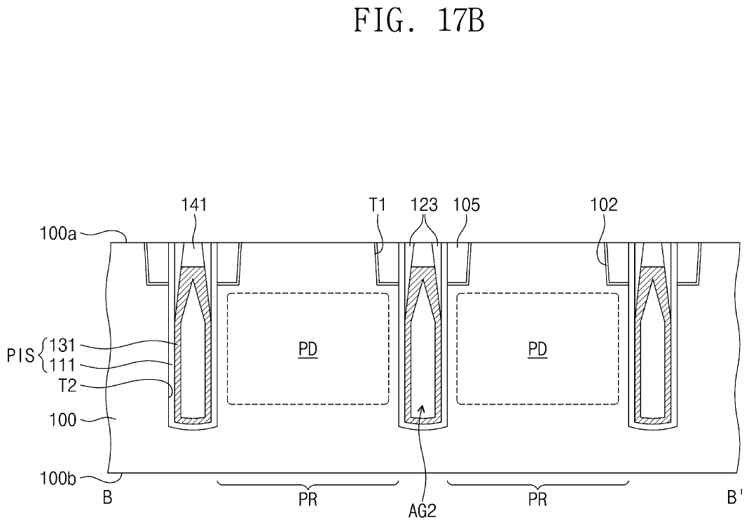

Referring to FIGS. 17A and 17B, a planarization process may be performed on the buried insulating film 140 so as to expose the upper surface of the mask pattern MP. Thereafter, the exposed mask pattern MP may be removed, and a planarization process may be performed on the device isolation film 105 and the buried insulating film 140 so that the first surface 100a of the semiconductor substrate 100 is exposed. Accordingly, the device isolation film 150 may be formed in the first trench T1, and the first buried insulating pattern 141 may be formed in the recess region RR.

An upper surface of the first buried insulating pattern 141 and an upper surface of the device isolation film 105 may be substantially coplanar with each other due to a planarization process for exposing the first surface 100a of the semiconductor substrate 100. Furthermore, the pixel isolation structure PIS including the sidewall insulating pattern 111 and the conductive pattern 131 may be formed in the second trench T2.

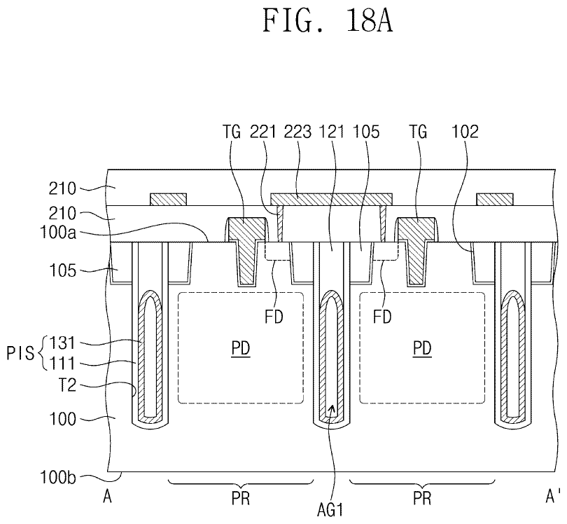

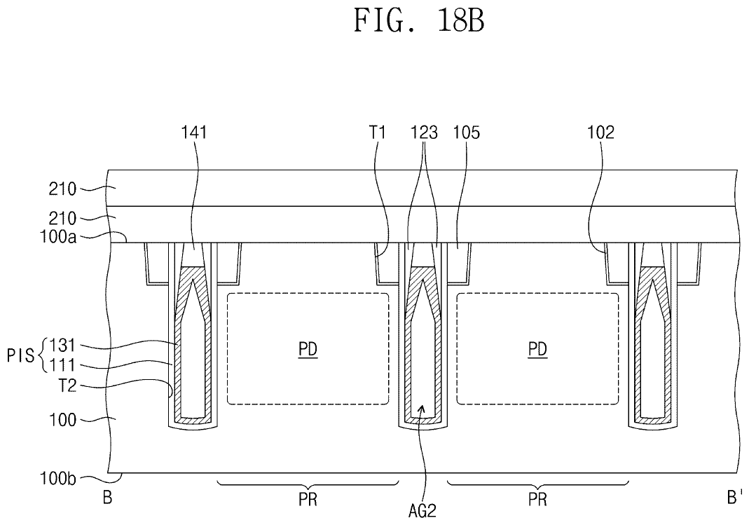

Referring to FIGS. 18A and 18B, MOS transistors constituting read-out circuits may be formed on the first surface 100a of the semiconductor substrate 100.

In detail, the transfer gate electrodes TG may be formed in each of the pixel regions PR and the dummy pixel regions DPR. Forming the transfer gate electrodes TG includes forming a gate recess region in each of the pixel regions PR by patterning the semiconductor substrate 100, forming a gate insulating film conformally covering an inner wall of the gate recess region, forming a gate conductive film filling the gate recess region, and patterning the gate conductive film.

Furthermore, when forming the transfer gate electrodes TG by patterning the gate conductive film, gate electrodes of read-out transistors may also be formed in each of the pixel regions PR.

After the transfer gate electrodes TG are formed, the floating diffusion regions FD may be formed in the semiconductor substrate 100 on one side of each of the transfer gate electrodes TG. The floating diffusion regions FD may be formed by ion injecting second-conductive type impurities. Furthermore, when forming the floating diffusion regions FD, source/drain impurity regions of the read-out transistors may be formed.

The interlayer insulating layers 210, the contact plugs 221, and the connection lines 223 may be formed on the first surface 100a of the semiconductor substrate 100.

The interlayer insulating layers 210 may cover the first surface 100a of the semiconductor substrate 100 and the transfer gate electrodes TG. The interlayer insulating layers 210 may be formed of a material having excellent gap fill characteristics, and formed to have a planarized upper surface. For example, high density plasma (HDP), Tonen SilaZene (TOSZ), spin on glass (SOG), undoped silica glass (USG), or the like may be used in the interlayer insulating layers 210.

The contact plugs 221 connected to the read-out transistors or the floating diffusion region FD may be formed in the interlayer insulating layer 210. The connection lines 223 may be formed between the interlayer insulating layers 210. Lines for electrically connecting the read-out transistors may be arranged without positional limitations. The contact plugs 221 and the connection lines 223 may be formed of, for example, copper (Cu), aluminum (Al), tungsten (W), titanium (Ti), molybdenum (Mo), tantalum (Ta), titanium nitride (TiN), tantalum nitride (TaN), zirconium nitride (ZrN), tungsten nitride (WN), and/or alloys thereof.

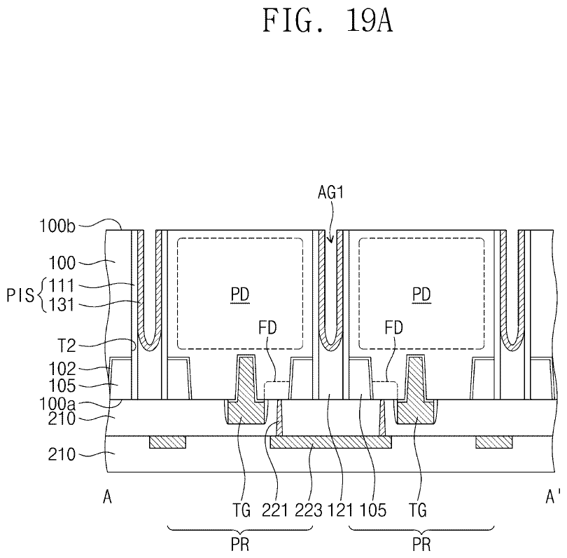

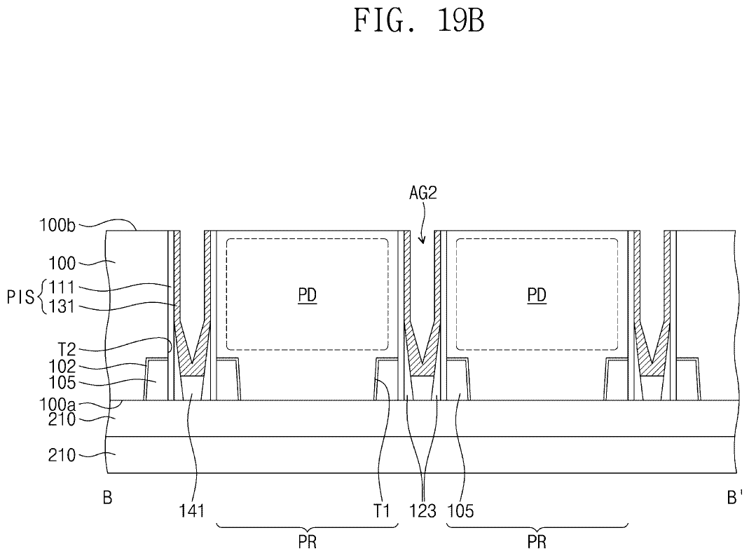

Referring to FIGS. 19A and 19B, a vertical thickness of the semiconductor substrate 100 may be reduced by performing a thinning process for removing a portion of the semiconductor substrate 100. The thinning process includes grinding or polishing the second surface 100b of the semiconductor substrate 100 and isotropically and anisotropically etching the same. In order to thin the semiconductor substrate 100, the semiconductor substrate 100 may be overturned. A portion of the semiconductor substrate 100 may be removed through a grinding or polishing process, and, thereafter, remaining surface defects of the semiconductor substrate 100 may be removed by performing an isotropic or anisotropic etching process.

For example, as the thinning process is performed on the semiconductor substrate 100, the bulk semiconductor substrate may be removed and the p-type epitaxial layer may remain. An exposed surface of the epitaxial layer may correspond to the second surface 100b of the semiconductor substrate 100. In embodiments, a thickness of the semiconductor substrate 100 remaining after the thinning process may be between8 μm and 15 μm.

Through the thinning process performed on the semiconductor substrate 100, a portion of the pixel isolation structure PIS may be exposed through the second surface 100b of the semiconductor substrate 100. During the thinning process performed on the semiconductor substrate 100, the sidewall insulating pattern 111 and the conductive pattern 131 may be partially removed, and the first and second air gaps AG1 and AG2 defined in the second trench T2 may be exposed through the second surface 100b of the semiconductor substrate 100.

Through the thinning process performed on the semiconductor substrate 100, the conductive pattern 131 and the sidewall insulating pattern 111 may have a lower surface at substantially the same level as the second surface 100b of the semiconductor substrate 100.

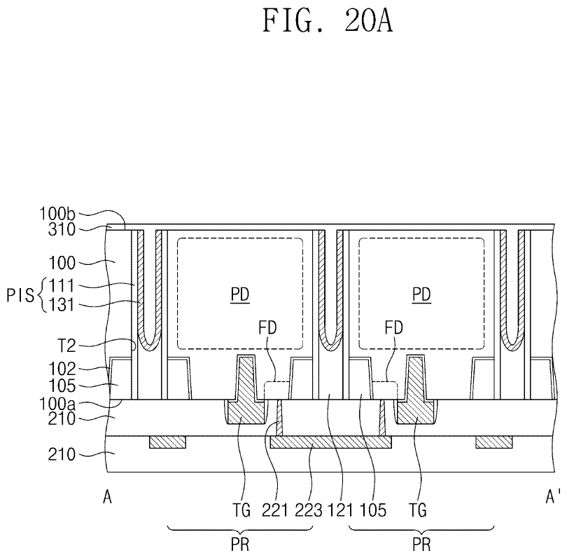

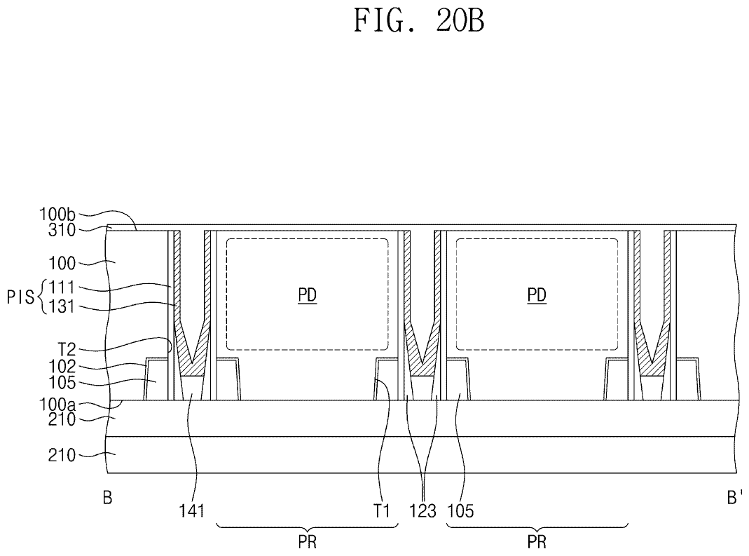

Referring to FIGS. 20A and 20B, the planarized insulating film 310 may be formed on the second surface 100b of the semiconductor substrate 100. The planarized insulating film 310 may cover a surface of the pixel isolation structure PIS and the second surface 100b of the semiconductor substrate 100. The planarized insulating film 310 may be formed by depositing metal oxide such as aluminum oxide and/or hafnium oxide. The planarized insulating film 310 may include a plurality of stacked insulating films.

The planarized insulating film 310 may be formed by performing a physical vapor deposition (PVD) (e.g., sputtering), a chemical vapor deposition, or an atomic layer deposition process.

When a deposition method with an excellent property of step coverage is used to form the planarized insulating film 310, a portion of the planarized insulating film 310 may fill gap regions of the conductive pattern 131. Alternatively, when a deposition method with a poor property of step coverage is used to form the planarized insulating film 310, the first and second air gaps AG1 and AG2 may be formed in the conductive pattern.

Referring to FIGS. 4A, 4B, and 4C, the lattice structure 320 may be formed on the planarized insulating film 310. The lattice structure 320 may include a light shielding pattern and/or a low refractive pattern. The light shielding pattern may include, for example, a metal material such as titanium, tantalum, or tungsten. The low refractive pattern may be formed of a material having a lower refractive index than the light shielding pattern. The low refractive pattern may be formed of an organic material and may have a refractive index between 1.1 and 1.3. For example, the lattice structure 320 may be a polymer layer including silica nanoparticles.

The lattice structure 320 may extend in the first direction D1 and the second direction D2 and may have a lattice form. The lattice structure 320 may overlap the semiconductor pattern 113 in a plan view.

Thereafter, the color filters 330 may be formed in correspondence to each of the pixel regions PR. The color filters 330 may include blue, red, and green color filters.

The micro lenses 340 may be respectively formed on the color filters 330. The micro lenses 340 may have a convex shape and a predetermined radius of curvature. The micro lenses 340 may be formed of a light transmissive resin.

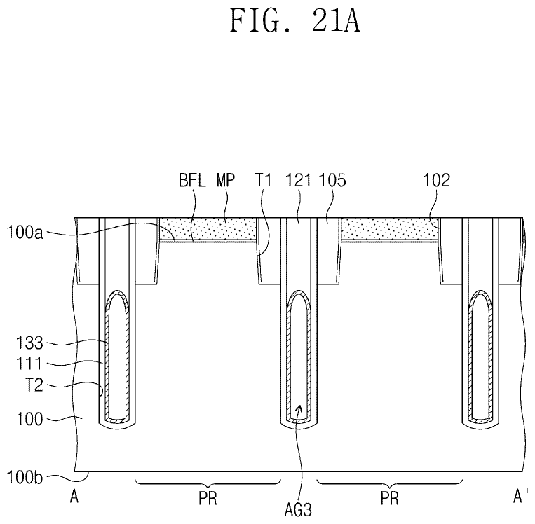

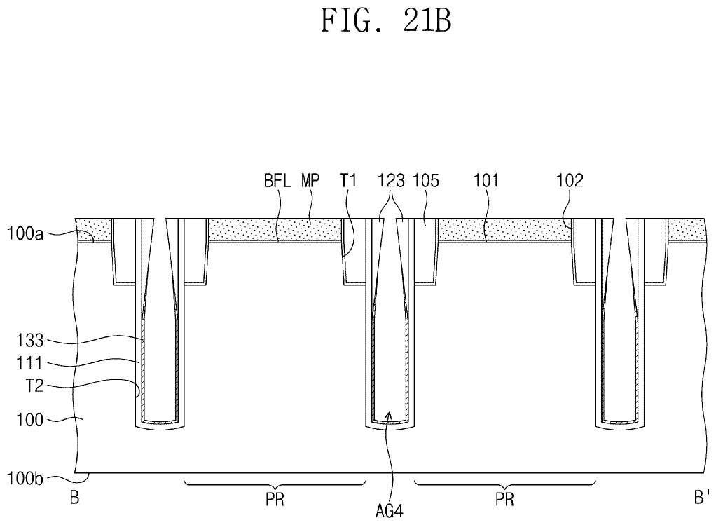

Hereinafter, a method for manufacturing an image sensor according to embodiments of the inventive concept will be described with reference to FIGS. 21A, 22A, 23A, 21B, 22B, and 23B.

FIGS. 21A, 21B, 22A, 22B, 23A, and 23B are cross-sectional views taken along line A-A′ and line B-B′ of FIG. 3 illustrating a method for manufacturing an image sensor according to embodiments of the inventive concept. In particular, FIGS. 21A, 22A, and 23A are cross-sectional views taken along line A-A′ of FIG. 3. FIGS. 21B, 22B, and 23B are cross-sectional views taken along line B-B′ of FIG. 3.

In the embodiments illustrated in FIGS. 21A, 22A, 23A, 21B, 22B, and 23B, the same reference numerals as the above-mentioned reference numerals refer to the same components, and descriptions thereof may not be provided.

Referring to FIGS. 21A and 21B, as described above with reference to FIGS. 13A and 13B, after the supporter patterns 121 and 123 are formed in the second trench T2, the conductive pattern 133 may be formed in the second trench T2.

Forming the conductive pattern 133 may include performing a deposition process of a conductive film and an etching process of the conductive film in-situ. The conductive film may be deposited using at least one of low-pressure chemical vapor deposition (LP-CVD), plasma-enhanced chemical vapor deposition (PE-CVD), or atomic layer deposition (ALD).

According to embodiments, a source gas including first-conductive type impurities may be used when forming the conductive pattern 133. The source gas may be provided to the first and second line regions of the second trench T2 through the opening formed by the second pattern parts 123 of the supporter patterns in the intersection region of the second trench T2. Accordingly, the conductive film may be deposited to a uniform thickness on the sidewall insulating pattern 111 and the first pattern part 121 of the supporter patterns, in the second trench T2.

The conductive pattern 133 may include polycrystalline silicon or amorphous silicon including first-conductive type impurities. As another example, the conductive pattern 133 may include a metal material, an organic/inorganic conductive material, or the like instead of a semiconductor material doped with first-conductive type impurities.

During a conductive film deposition process for forming the conductive pattern 133, the source gas may include a first gas including a silane-based compound and a second gas including a compound containing the impurities such as boron (B). The conductive film may be deposited via chemical reaction between the first gas and the second gas. The conductive film formed in this manner may have a uniform concentration of impurities regardless of a location. For example, during the deposition process of the conductive pattern 133, SiH₄ (or Si₂H₆) and BCl₃ (or B₂H₆) may be used, and the deposition process may be performed at a low temperature between 300° C. and 530° C.

An etchant gas including chlorine may be used during the etching process of the conductive film. During the etching process of the conductive film, an etching rate may be higher at the first surface 100a of the semiconductor substrate 100 than at the inner wall of the second trench T2. Accordingly, since the conductive film deposited on an upper surface of the supporter insulating film 120 of the semiconductor substrate 100 is etched, the upper surface of the supporter insulating film 120 may be exposed, and the conductive film may remain in the second trench T2.

The deposition and etching processes of the conductive film may be repeated until an upper surface of the conductive pattern 133 is located at a lower level than a bottom surface of the first trench T1. Alternatively, the deposition and etching processes of the conductive film may be repeated until the upper surface of the conductive pattern 133 is located at a level lower than the first surface 100a of the semiconductor substrate 100 and higher than the bottom surface of the first trench T1.

The conductive pattern 133 formed as described above may define a third air gap AG3 in the first and second line regions of the second trench T2, and may include a gap region AG4 defined by sidewall portions and a connection portion in the intersection region of the second trench T2. In the intersection region of the second trench T2, the sidewall portions of the conductive pattern 133 may have a spacer shape that is tapered toward the first surface 100a of the semiconductor substrate 100.

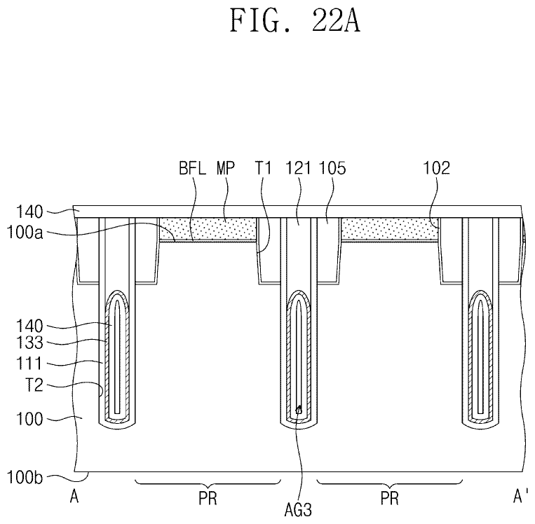

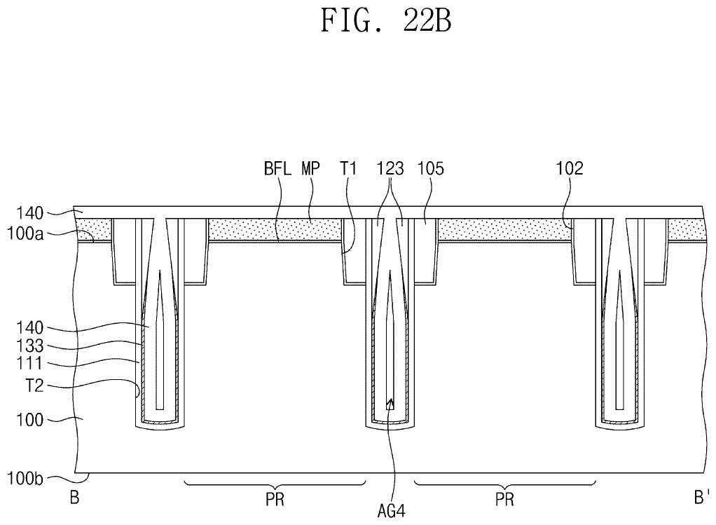

Referring to FIGS. 22A and 22B, the buried insulating film 140 may be deposited on the conductive pattern 133.

The buried insulating film 140 may be formed using a film-forming technique with an excellent property of step coverage, such as chemical vapor deposition (CVD) or atomic layer deposition (ALD). In this case, the buried insulating film 140 may cover a surface of the conductive pattern 133 with a substantially uniform thickness in the second trench T2. The buried insulating film 140 may close an opening defined by the second pattern parts 123 of the supporter patterns in the intersection region of the second trench T2. While the buried insulating film 140 is being deposited, an air gap may be formed inside the buried insulating film 140 in the second trench T2. The buried insulating film 140 may include, for example, silicon oxide, silicon nitride, and/or silicon oxynitride.

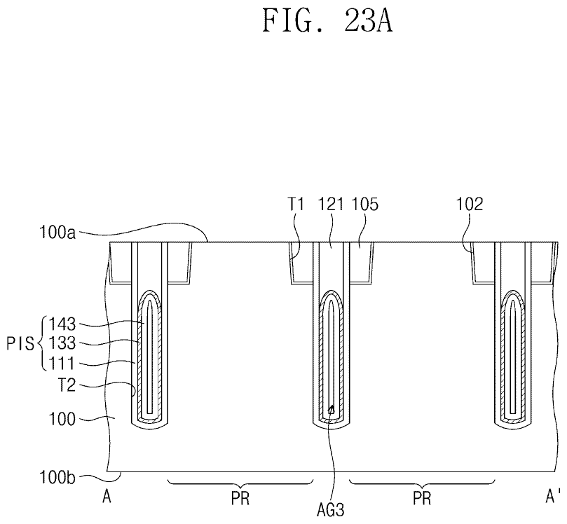

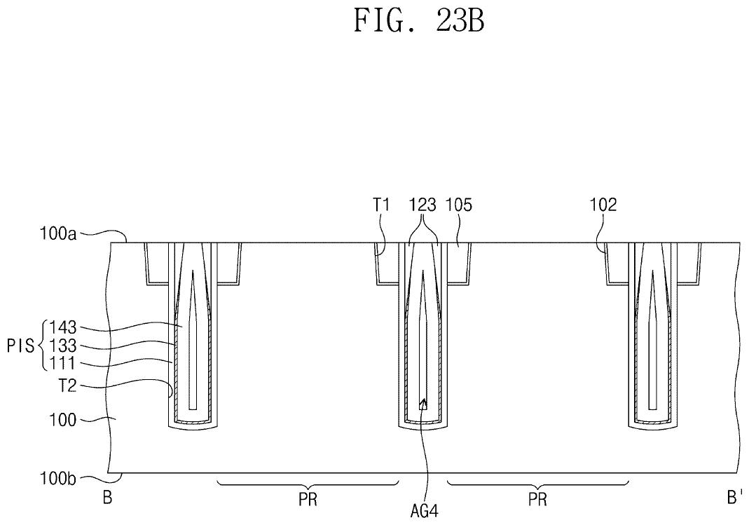

Referring to FIGS. 23A and 23B, the sidewall insulating pattern 111, the conductive pattern 133, and the second buried insulating pattern 143 may be formed in the second trench T2 by planarizing the buried insulating film 140 so that an upper surface of the mask pattern MP is exposed. Accordingly, the pixel isolation structure PIS may be formed in the second trench T2.

Thereafter, the mask pattern MP may be removed, and the device isolation film 105 may be formed in the first trench T1 by planarizing the device isolation film 105 so that the first surface 100a of the semiconductor substrate 100 is exposed. An upper surface of the second buried insulating pattern 143 and an upper surface of the device isolation film 105 may be substantially coplanar with each other due to a planarization process for exposing the first surface 100a of the semiconductor substrate 100.

Thereafter, as illustrated in FIGS. 7A and 7B, the read-out circuit layer 20 may be formed on the first surface 100a of the semiconductor substrate 100, and the light transmissive layer 30 may be formed through a thinning process for the second surface 100b of the semiconductor substrate 100.

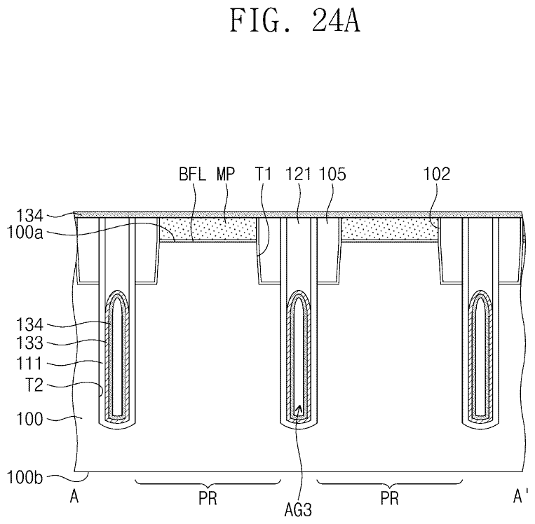

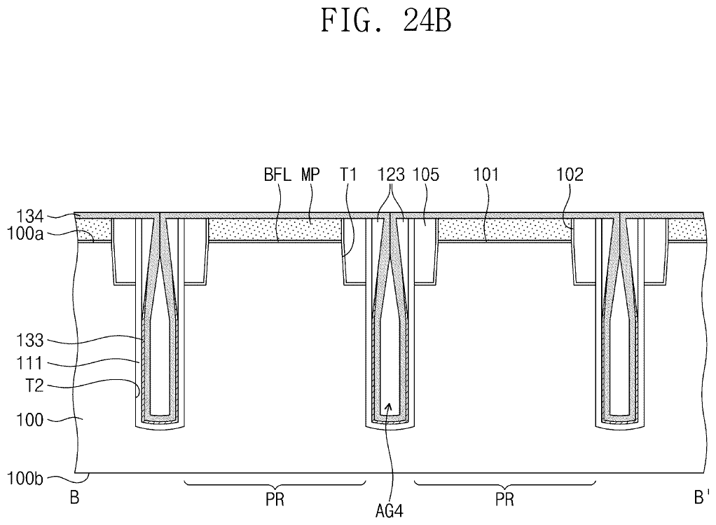

Hereinafter, a method for manufacturing an image sensor according to embodiments of the inventive concept will be described with reference to FIGS. 24A, 25A, 26A, 24B, 25B, and 26B.

FIGS. 24A, 24B, 25A, 25B, 26A, and 26B are cross-sectional views taken along line A-A′ and line B-B′ of FIG. 3 illustrating a method for manufacturing an image sensor according to embodiments of the inventive concept. In particular, FIGS. 24A, 25A, and 26A are cross-sectional views taken along line A-A′ of FIG. 3. FIGS. 24B, 25B, and 26B are cross-sectional views taken along line B-B′ of FIG. 3.

Referring to FIGS. 24A and 24B, as described above with reference to FIGS. 21A and 21B, the conductive pattern 133 may be formed in the second trench T2. The conductive pattern 133 may be a semiconductor film doped with first-conductive type (e.g., P-type) impurities. Thereafter, a buried semiconductor film 134 may be deposited on the conductive pattern 133. The buried semiconductor film 134 may be a semiconductor film undoped with impurities or a semiconductor film having a lower impurity concentration than an impurity concentration in the conductive pattern 133.

The buried semiconductor film 134 may be formed using a film-forming technique with an excellent property of step coverage, such as chemical vapor deposition (CVD) or atomic layer deposition (ALD). In this case, the buried semiconductor film 134 may cover a surface of the conductive pattern 133 with a substantially uniform thickness in the second trench T2.

The buried semiconductor film 134 may close the opening formed by the second pattern parts 123 of the supporter patterns, and while the buried semiconductor film 134 is being deposited, gap regions AG3 and AG4 may be formed in the first and second line regions of the second trench T2 and in the intersection region of the second trench T2.

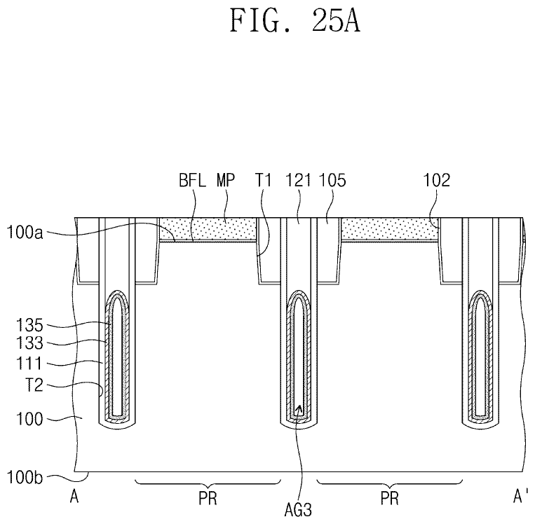

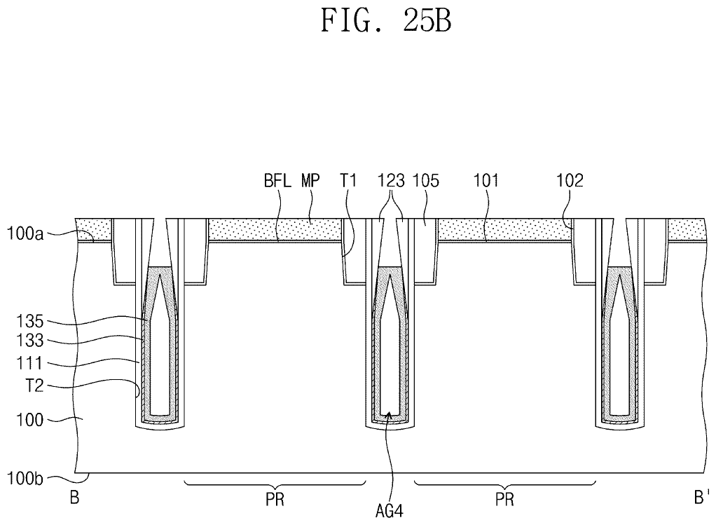

Referring to FIGS. 25A and 25B, an anisotropic etching process (e.g., etch-back process) may be performed on the buried semiconductor film 134 so as to expose the upper surface of the mask pattern MP. Accordingly, the buried semiconductor pattern 135 may be formed in the second trench T2. Furthermore, when performing the anisotropic etching process on the buried semiconductor film 134, a recess region RR exposing the inclined surfaces of the supporter pattern 123 may be formed through over-etching.

The buried semiconductor pattern 135 may have an upper surface positioned at a lower level than the first surface 100a of the semiconductor substrate 100 in the intersection region of the second trench T2. The upper surface of the buried semiconductor pattern 135 may be substantially flat in the intersection region.

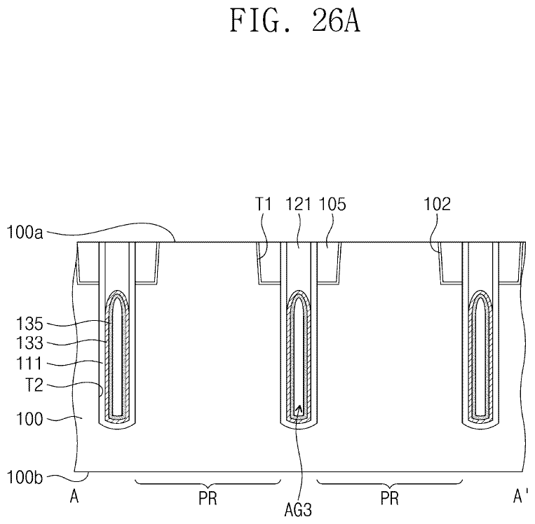

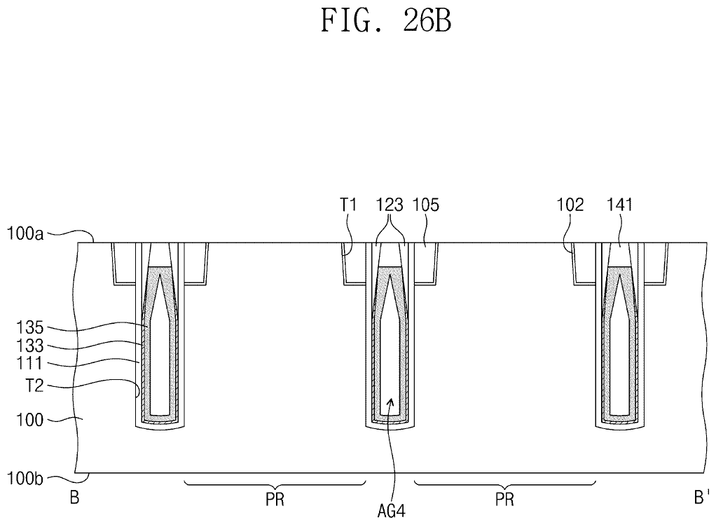

Referring to FIGS. 26A and 26B, as described above with reference to FIGS. 16A, 16B, 17A, and 17B, the first buried insulating pattern 141 may be formed in the recess region RR. The upper surface of the first buried insulating pattern 141 may be substantially coplanar with the upper surface of the device isolation film 105. Furthermore, the pixel isolation structure PIS including the sidewall insulating pattern 111, the conductive pattern 135, and the buried semiconductor pattern 135 may be formed in the second trench T2.

Thereafter, as illustrated in FIGS. 4A and 4B, the read-out circuit layer 20 may be formed on the first surface 100a of the semiconductor substrate 100, and the light transmissive layer 30 may be formed through a thinning process for the second surface 100b of the semiconductor substrate 100.

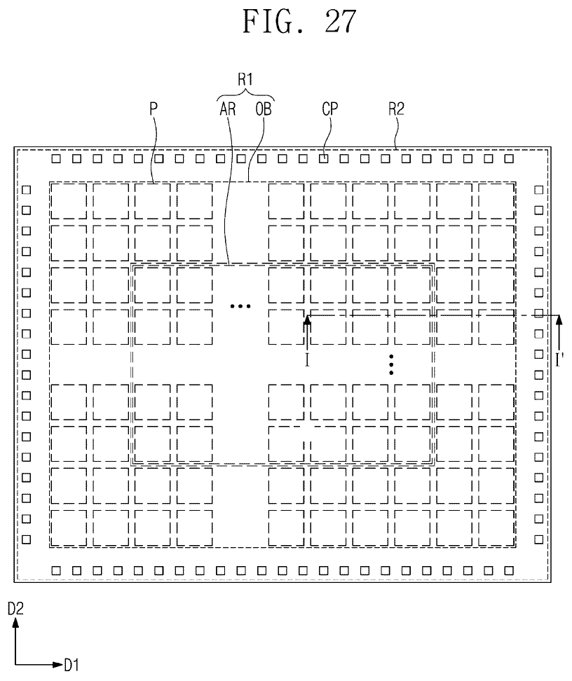

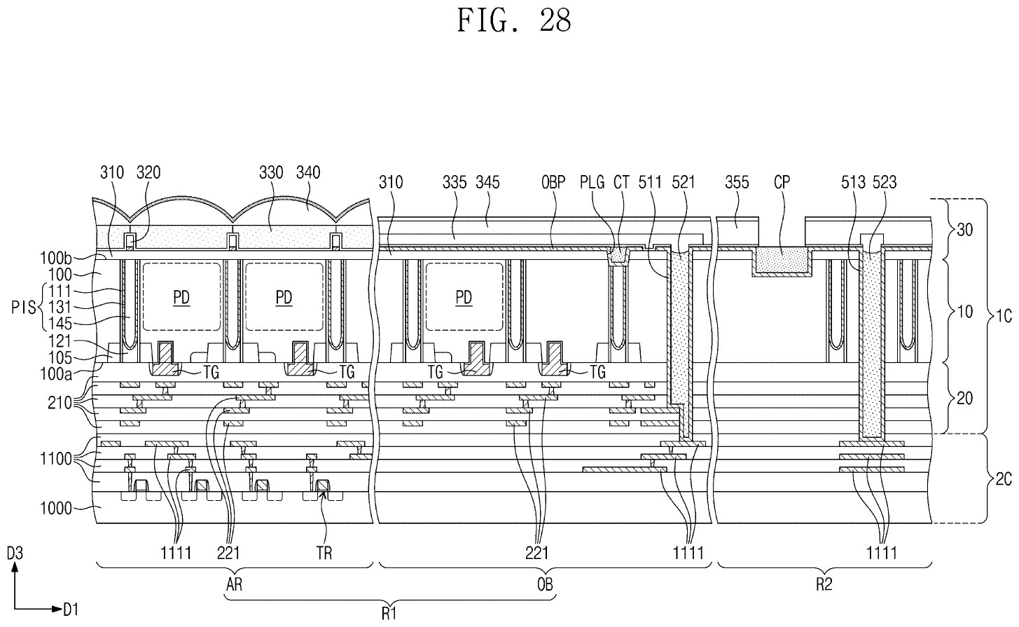

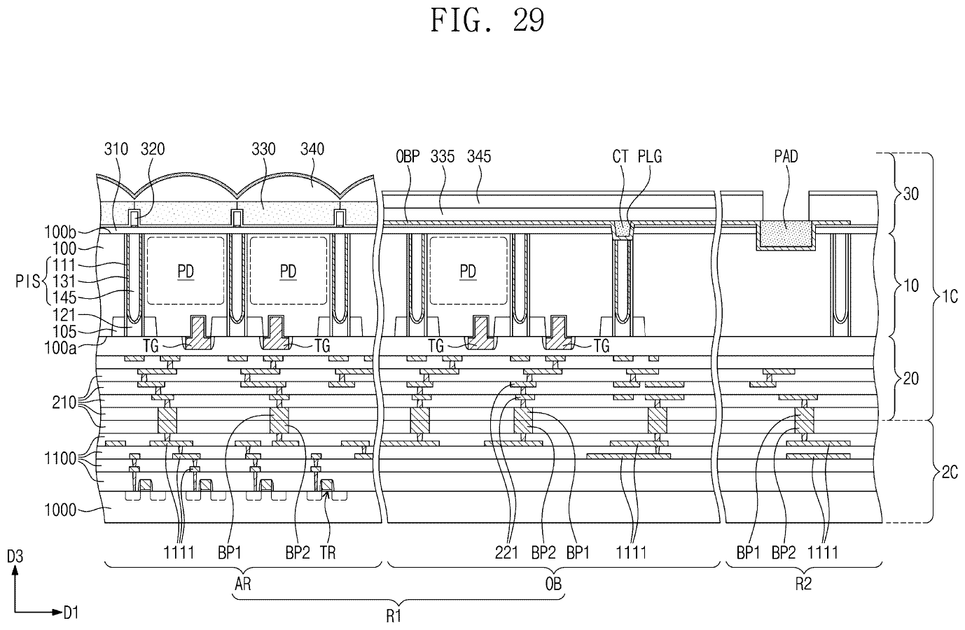

FIG. 27 is a schematic plan view of an image sensor including a semiconductor device according to embodiments of the inventive concept. FIGS. 28 and 29 are cross-sectional views of an image sensor, taken along line I-I′ of FIG. 27, according to embodiments of the inventive concept.

Referring to FIGS. 27 and 28, the image sensor may include a sensor chip 1C and a logic chip 2C. The sensor chip 1C may include a pixel array region R1 and a pad region R2.

The pixel array region R1 may include a plurality of unit pixels P arranged two-dimensionally along the first direction D1 and the second direction D2 that, respectively, intersect each other. Each of the unit pixels P may include a photoelectric conversion element and reading elements. An electric signal generated due to incident light may be output from each of the unit pixels P of the pixel array region R1.

The pixel array region R1 may include a light reception region AR and a light shielding region OB. The light shielding region OB may surround the light reception region AR in a plan view. Namely, the light shielding region OB may be disposed above, below, and to the left and right of the light reception region AR in a plan view. Reference pixels on which light is not incident are provided in the light shielding region OB, and a magnitude of an electric signal sensed in the unit pixels P may be calculated by comparing an amount of charges sensed in the unit pixels P of the light reception region AR with a reference amount of charges generated in the reference pixels.

A plurality of conductive pads CP used to input/output control signals, photoelectric signals, and the like may be arranged in the pad region R2. The pad region R2 may surround the pixel array region R1 in a plan view so as to facilitate electrical connection to external elements. The conductive pads CP may input/output an electric signal generated in the unit pixels P to an external device.

The sensor chip 1C in the light reception region AR may include the same technical features as the image sensor described above. That is, the sensor chip 1C may include the photoelectric conversion layer 10 between the read-out circuit layer 20 and the light transmissive layer 30 in a vertical direction, as described above. The photoelectric conversion layer 10 of the sensor chip 1C may include the semiconductor substrate 100, the pixel isolation structure PIS defining pixel regions, and the photoelectric conversion regions PD provided in the pixel regions, as described above. The pixel isolation structure PIS may have substantially the same structure in the light reception region AR and the light shielding region OB.

The light transmissive layer 30 may include a light shielding pattern OBP, a back contact plug PLG, a contact pattern CT, a filtering film 335, and an organic film 345 in the light shielding region OB.

A portion of the pixel isolation structure PIS may be connected to the back contact plug PLG in the light shielding region OB.

In detail, the conductive pattern of the pixel isolation structure PIS may be connected to the back contact plug PLG in the light shielding region OB. A negative bias may be applied to the semiconductor pattern 113 through the contact pattern CT and the back contact plug PLG. Accordingly, a dark current generated at a boundary between the pixel isolation structure PIS and the semiconductor substrate 100 may be reduced.

The back contact plug PLG may have a larger width than that of the pixel isolation structure PIS. The back contact plug PLG may include metal and/or metal nitride. For example, the back contact plug PLG may include titanium and/or titanium nitride.

The contact pattern CT may be buried in a contact hole in which the back contact plug PLG is formed. The contact pattern CT may include a material that is different from a material of the back contact plug PLG. For example, the contact pattern CT may include aluminum (Al).

The contact pattern CT may be electrically connected to the conductive pattern of the pixel isolation structure PIS. A negative bias may be applied to the conductive pattern of the pixel isolation structure PIS through the contact pattern CT, and may be transferred from the light shielding region OB to the light reception region AR.

In the light shielding region OB, the light shielding pattern OBP may continuously extend from the back contact plug PLG and may be disposed on an upper surface of the planarized insulating film 310. That is, the light shielding pattern OBP may include the same material as the back contact plug PLG. The light shielding pattern OBP may include metal and/or metal nitride. For example, the light shielding pattern OBP may include titanium and/or titanium nitride. The light shielding pattern OBP may not extend to the light reception region AR of a pixel array.

The light shielding pattern OBP may block light from being incident on the photoelectric conversion regions PD provided to the light shielding region OB. The photoelectric conversion regions PD may output a noise signal without outputting a photoelectric signal in reference pixel regions of the light shielding region OB. The noise signal may be generated due to electrons generated by dark current or heat generation.

The filtering film 335 may cover the light shielding pattern OBP in the light shielding region OB. The filtering film 335 may block light of a different wavelength from that blocked by the color filters 330. For example, the filtering film 335 may block infrared light. The filtering film 335 may include a blue color filter but is not limited thereto.

The organic film 345 and a passivation film may be provided on the filtering film 335 in the edge region ER. The organic film 345 may include the same material as the micro lenses 340.

In the light shielding region OB, a first penetrating conductive pattern 511 may penetrate the semiconductor substrate 100 and may be electrically connected to the connection line 223 of the read-out circuit layer 20 and a wiring structure 1111 of the logic chip 2C. The first penetrating conductive pattern 511 may have a first bottom surface and a second bottom surface located at different levels. A first buried pattern 521 may be provided in the first penetrating conductive pattern 511. The first buried pattern 521 may include a low refractive material and have insulating properties.

In the pad region R2, the conductive pads CP may be provided to the second surface 100b of the semiconductor substrate 100. The conductive pads CP may be buried in the second surface 100b of the semiconductor substrate 100. For example, the conductive pads CP may be provided in a pad trench formed in the second surface 100b of the semiconductor substrate 100 in the pad region R2. The conductive pads CP may include metal such as aluminum, copper, tungsten, titanium, tantalum, and/or alloys thereof. A bonding wire may be bonded to the conductive pads CP in a mounting process of an image sensor. The conductive pads CP may be electrically connected to an external device through the bonding wire.

In the pad region R2, a second penetrating conductive pattern 513 may penetrate the semiconductor substrate 100 and may be electrically connected to the wiring structure 1111 of the logic chip 2C. The second penetrating conductive pattern 513 may extend to the second surface 100b of the semiconductor substrate 100 and may be electrically connected to the conductive pads CP. A portion of the second penetrating conductive pattern 513 may cover bottom surfaces and sidewalls of the conductive pads CP. A second buried pattern 523 may be provided in the second penetrating conductive pattern 513. The second buried pattern 523 may include a low refractive material and have insulating properties. In the pad region R2, pixel isolation structures may be provided around the second penetrating conductive pattern 513.

The logic chip 2C may include a logic semiconductor substrate 1000, logic circuits TR, wiring structures 1111 connected to the logic circuits TR, and logic interlayer insulating layers 1100. An uppermost layer among the logic interlayer insulating layers 1100 may be bonded to the read-out circuit layer 20 of the sensor chip 1C. The logic chip 2C may be electrically connected to the sensor chip 1C through the first penetrating conductive pattern 511 and the second penetrating conductive pattern 513.

In an example, although the sensor chip 1C and the logic chip 2C have been described as being electrically connected to each other through the first and second penetrating conductive patterns 511 and 513, embodiments of the inventive concept are not limited thereto.

According to the embodiment illustrated in FIG. 29, the first and second penetrating conductive patterns illustrated in FIG. 28 may be omitted, and the sensor chip 1C and the logic chip 2C may be electrically connected to each other by directly bonding bonding pads BP1 and BP2 provided to uppermost metal layers of the sensor chip 1C and the logic chip 2C.

In detail, the sensor chip 1C of the image sensor may include first bonding pads BP1 provided to an uppermost metal layer of the read-out circuit layer 20, and the logic chip 2C may include second bonding pads BP2 provided to an uppermost metal layer of the wiring structure 1111. The first and second bonding pads BP1 and BP2 may include, for example, at least one of tungsten (W), aluminum (Al), copper (Cu), tungsten nitride (WN), tantalum nitride (TaN), and/or titanium nitride (TiN).

The first bonding pads BP1 of the sensor chip 1C and the second bonding pads BP2 of the logic chip 2C may be directly and electrically connected to each other through hybrid bonding. The hybrid bonding may refer to bonding for fusing two components including homogeneous materials at an interface therebetween. For example, when the first and second bonding pads BP1 and BP2 are formed of copper (Cu), the first and second bonding pads BP1 and BP2 may be physically and electrically connected through copper (Cu)-copper (Cu) bonding. Furthermore, a surface of an insulating film of the sensor chip 1C and a surface of an insulating film of the logic chip 2C may be bonded through dielectric-dielectric bonding.

According to embodiments of the inventive concept, the amount of a conductive pattern having a high light absorption rate may be minimized in a pixel isolation structure. Accordingly, absorption of incident light into a semiconductor material of the pixel isolation structure may be reduced, and dark current generated due to defects at the interface between the semiconductor substrate and the pixel isolation structure may be reduced by applying a negative voltage to the semiconductor material of the pixel isolation structure.

Furthermore, an increase in an aspect ratio of a second trench, in which a second pixel isolation structure is provided, due to an increase in a pixel size and the number of pixels may cause pixel regions to fall or lean, and this limitation may be overcome by providing a supporter pattern between the pixel regions.

Therefore, structural stability and electrical and optical characteristics of an image sensor may be simultaneously improved.

Although example embodiments of the present disclosure have been described, it will be understood that the present disclosure is not limited to these embodiments and various changes and modifications may be apparent to one of ordinary skill in the art within the scope of the present disclosure as hereinafter claimed. Therefore, it will be understood that embodiments as described above are intended to be illustrative and non-restrictive in all respects.

What is claimed is:

1. An image sensor comprising:
a semiconductor substrate having a first surface and a second surface opposite to the first surface; and
a pixel isolation structure vertically extending into the semiconductor substrate and defining a plurality of pixel regions,
wherein the pixel isolation structure includes:
a sidewall insulating pattern in contact with the semiconductor substrate;
a first buried pattern on the sidewall insulating pattern; and
a second buried pattern on the first buried pattern,
wherein a first isolation portion of the pixel isolation structure extends in a first direction, a second isolation portion of the pixel isolation structure extends in a second direction intersecting the first direction, and a third isolation portion of the pixel isolation structure is at an intersection of the first isolation portion and the second isolation portion, and
wherein the first buried pattern includes sidewall portions on the sidewall insulating pattern and a connection portion extending between the sidewall portions, in each of the first, second, and third isolation portions.

2. The image sensor of claim 1, further comprising:
a read-out circuit layer including read-out circuits on the first surface of the semiconductor substrate; and
a light transmissive layer on the second surface of the semiconductor substrate,
wherein the connection portion of the first buried pattern is closer to the first surface of the semiconductor substrate than to the second surface of the semiconductor substrate.

3. The image sensor of claim 1, wherein, in the first and second isolation portions of the pixel isolation structure, the connection portion of the first buried pattern has a curved surface that is convex toward the first surface of the semiconductor substrate.

4. The image sensor of claim 1, wherein, in the third isolation portion of the pixel isolation structure, the connection portion of the first buried pattern has a flat surface that faces the first surface of the semiconductor substrate.

5. The image sensor of claim 4, further comprising:
a first buried insulating pattern on the flat surface of the first buried pattern,
wherein a surface of the first buried insulating pattern is substantially coplanar with the first surface of the semiconductor substrate.

6. The image sensor of claim 1, further comprising:
a supporter pattern on the first buried pattern between adjacent ones of the plurality of pixel regions,
wherein a surface of the supporter pattern is substantially coplanar with the first surface of the semiconductor substrate.

7. The image sensor of claim 1, wherein the first buried pattern includes a conductive material.

8. The image sensor of claim 1, wherein the first buried pattern includes a first pattern on the sidewall insulating pattern and a second pattern on the first pattern,
wherein the first pattern includes a semiconductor material doped with impurities, and
wherein the second pattern includes a semiconductor material undoped with impurities.

9. The image sensor of claim 1, wherein the first buried pattern includes a conductive pattern on the sidewall insulating pattern and a second buried insulating pattern on the conductive pattern.

10. The image sensor of claim 9, wherein the second buried insulating pattern is between the second buried pattern and the conductive pattern.

11. The image sensor of claim 1, wherein the second buried pattern includes at least one of a void or a dielectric film.

12. The image sensor of claim 1, wherein the second buried pattern includes metal oxide.

13. An image sensor comprising:
a semiconductor substrate having a first surface and a second surface opposite to the first surface; and
a pixel isolation structure vertically extending into the semiconductor substrate and defining a plurality of pixel regions,
wherein the pixel isolation structure includes:
a sidewall insulating pattern in contact with the semiconductor substrate;
a conductive pattern on the sidewall insulating pattern; and
a buried pattern on the conductive pattern,
wherein a first isolation portion of the pixel isolation structure extends in a first direction, a second isolation portion of the pixel isolation structure extends in a second direction intersecting the first direction, and a third isolation portion of the pixel isolation structure is at an intersection of the first isolation portion and the second isolation portion, and
wherein the conductive pattern includes sidewall portions on the sidewall insulating pattern and a connection portion extending between the sidewall portions, in each of the first, second, and third isolation portions.

14. The image sensor of claim 13, wherein, in the first and second isolation portions, the connection portion of the conductive pattern has a curved surface that is convex toward the first surface of the semiconductor substrate, and
wherein, in the third isolation portion, the connection portion of the conductive pattern has a flat surface that faces the first surface of the semiconductor substrate.

15. The image sensor of claim 13, wherein, in the first and second isolation portions, the connection portion of the conductive pattern is spaced apart from the first surface of the semiconductor substrate by a first distance,
wherein, in the third isolation portion, the connection portion of the conductive pattern is spaced apart from the first surface of the semiconductor substrate by a second distance, and
wherein the second distance is less than the first distance.

16. The image sensor of claim 13, further comprising:
a first buried insulating pattern on the connection portion of the conductive pattern in the third isolation portion,
wherein a surface of the first buried insulating pattern is substantially coplanar with the first surface of the semiconductor substrate.

17. The image sensor of claim 13, wherein the buried pattern includes at least one of a void or metal oxide.

18. The image sensor of claim 13, wherein the conductive pattern includes:
a first pattern in contact with the sidewall insulating pattern and including a semiconductor material doped with impurities; and
a second pattern on the first pattern and including a semiconductor material undoped with impurities.

19. The image sensor of claim 13, further comprising:
a supporter pattern on the conductive pattern between adjacent ones of the plurality of pixel regions,
wherein the supporter pattern includes a first pattern part in contact with the connection portion of the conductive pattern in the first and second isolation portions, and second pattern parts in contact with the connection portion of the conductive pattern in the third isolation portion, and
wherein the second pattern parts are spaced apart from each other.

20. An image sensor comprising:
a semiconductor substrate of a first conductivity type and having a first surface and a second surface opposite to each other;
a pixel isolation structure vertically extending into the semiconductor substrate and defining pixel regions;
a photoelectric conversion region in the semiconductor substrate in a respective one of the pixel regions and including second conductivity type impurities;
a device isolation film adjacent to the first surface of the semiconductor substrate and defining an active portion in the semiconductor substrate in the respective one of the pixel regions;
a transfer gate electrode on the active portion of the respective one of the pixel regions;
a contact plug extending into a portion of the pixel isolation structure and electrically connected to a first buried pattern of the pixel isolation structure;
color filters on the second surface of the semiconductor substrate and corresponding to respective ones of the pixel regions;
a lattice structure between adjacent ones of the color filters; and
micro lenses on respective ones of the color filters,
wherein the pixel isolation structure includes:
a sidewall insulating pattern in contact with the semiconductor substrate;
the first buried pattern on the sidewall insulating pattern; and
a second buried pattern on the first buried pattern,
wherein a first isolation portion of the pixel isolation structure extends in a first direction, a second isolation portion of the pixel isolation structure extends in a second direction intersecting the first direction, and a third isolation portion of the pixel isolation structure is at an intersection of the first isolation portion and the second isolation portion, and
wherein the first buried pattern includes sidewall portions on the sidewall insulating pattern and a connection portion extending between the sidewall portions in each of the first, second, and third isolation portions.
